(19) United States
(12) Patent Application Publication
(10) Pub. No.: US 2026/0094625 A1
(43) Pub. Date: Apr. 2, 2026

(54) MEMORY DEVICE AND METHOD OF FORMING THE SAME

(71) Applicant: TAIWAN SEMICONDUCTOR MANUFACTURING COMPANY, LTD., Hsinchu (TW)

(72) Inventors: Kian-Long LIM, Hsinchu (TW); Jui-Lin CHEN, Hsinchu (TW)

(21) Appl. No.: 19/037,991

(22) Filed: Jan. 27, 2025

Related U.S. Application Data
(60) Provisional application No. 63/701,274, filed on Sep. 30, 2024.

(51) Int. Cl. G11C 5/06; G11C 11/419; H10B 10/00

(52) U.S. Cl. CPC G11C 5/063; G11C 11/419; H10B 10/125

(57) ABSTRACT

A device includes a cross-latch, a first, second, third and fourth transistor and a first read bit line. The first transistor includes a first gate extending in a first direction, and is on a first level. The second transistor includes a second gate on a second level below the first level. The third transistor is coupled to the first storage node, and includes a third gate on the first level. The fourth transistor is coupled to a first storage node, and includes a fourth gate on the second level. The first read bit line extends in a second direction, is on a first metal layer above a front-side of a substrate, and is coupled to the third and fourth transistor. The third and fourth transistor correspond to a first port of the device.

### PRIORITY CLAIM

This application claims the benefit of U.S. Provisional Application No. 63/701,274, filed Sep. 30, 2024, which is incorporated herein by reference in its entirety.

### BACKGROUND

The semiconductor integrated circuit (IC) industry has produced a wide variety of digital devices to address issues in a number of different areas. Some of these digital devices, such as memory macros, are configured for the storage of data. As ICs have become smaller and more complex, the resistance of conductive lines within these digital devices is also changed affecting the operating voltages of these digital devices and overall IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a memory circuit, in accordance with some embodiments.

FIGS. 2A-2B are corresponding circuit diagrams of corresponding memory cells usable in FIG. 1, in accordance with some embodiments.

FIGS. 3A-3F are corresponding diagrams of corresponding portions of a layout design of a corresponding integrated circuit, in accordance with some embodiments.

FIGS. 4A-4L are diagrams of an integrated circuit, in accordance with some embodiments.

FIGS. 5A-5E are diagrams of an integrated circuit, in accordance with some embodiments.

FIG. 6A is a diagram of a portion of a floorplan of an integrated circuit, in accordance with some embodiments.

FIG. 6B is a diagram of a portion of a floorplan of the integrated circuit, in accordance with some embodiments.

FIG. 7 is a timing diagram of waveforms of the memory circuit in FIG. 2A, in accordance with some embodiments.

FIG. 8 is a functional flow chart of a method of manufacturing an integrated circuit, in accordance with some embodiments.

FIG. 9 is a flow chart of a method of manufacturing an integrated circuit, in accordance with some embodiments.

FIG. 10 is a flowchart of a method of generating a layout design of an integrated circuit, in accordance with some embodiments.

FIG. 11 is a schematic view of a system for designing an IC layout design and manufacturing an IC circuit, in accordance with some embodiments.

FIG. 12 is a block diagram of an IC manufacturing system, and an IC manufacturing flow associated therewith, in accordance with at least one embodiment of the present disclosure.

FIGS. 13A-13B are a flowchart of a method of operating a circuit, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a multi-port memory cell includes a cross-latch.

In some embodiments, the cross-latch includes a first storage node and a second storage node.

In some embodiments, the multi-port memory cell further includes a first transistor of a first type. In some embodiments, the first transistor includes a first gate extending in a first direction. In some embodiments, the first gate is on a first level.

In some embodiments, the multi-port memory cell further includes a second transistor of a second type different from the first type. In some embodiments, the second transistor includes a second gate. In some embodiments, the second gate is on a second level below the first level.

In some embodiments, the multi-port memory cell further includes a third transistor of the first type.

In some embodiments, third transistor is coupled to the first storage node. In some embodiments, the third transistor includes a third gate on the first level.

In some embodiments, the multi-port memory cell further includes a fourth transistor of the second type.

In some embodiments, the fourth transistor is coupled to the first storage node. In some embodiments, the fourth transistor includes a fourth gate on the second level.

In some embodiments, the multi-port memory cell further includes a first read bit line.

In some embodiments, first read bit line extends in a second direction different from the first direction. In some embodiments, the first read bit line is on a first metal layer above a front-side of a substrate. In some embodiments, the first read bit line is coupled to the third transistor and the fourth transistor.

In some embodiments, the third transistor and the fourth transistor correspond to at least a first port of the multi-port memory cell.

In some embodiments, the multi-port memory cell further includes a first gate isolation layer between the first gate and the second gate. In some embodiments, the first gate isolation layer electrically insulates the first gate and the second gate from each other.

In some embodiments, by electrically insulating the first gate and the second gate from each other, the memory cell can be used as a multi-port memory cell with the first port and the second port that occupies less area than other approaches.

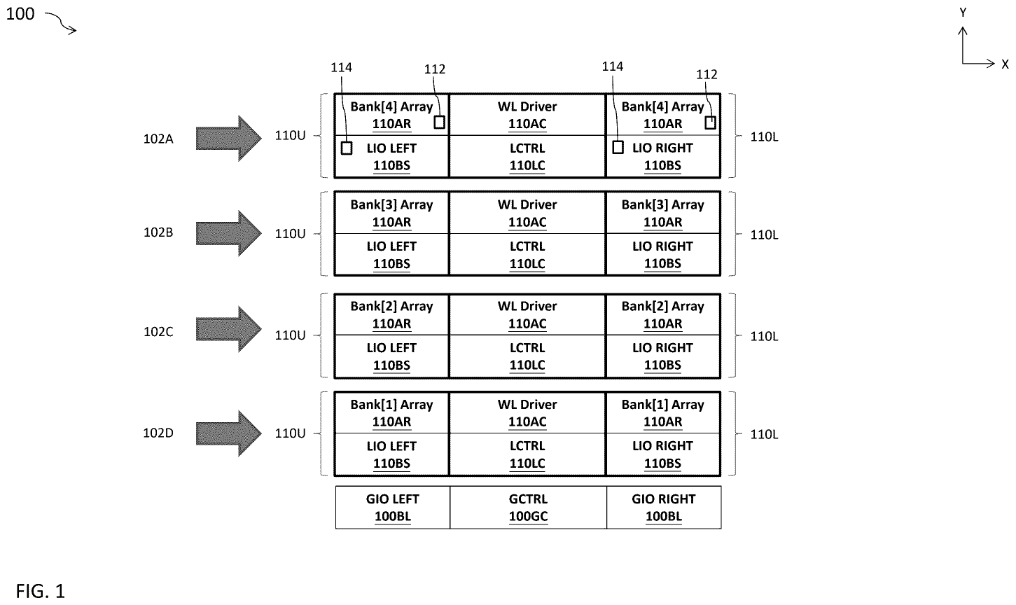

FIG. 1 is a block diagram of a memory circuit 100, in accordance with some embodiments.

FIG. 1 is simplified for the purpose of illustration. In some embodiments, memory circuit 100 includes various elements in addition to those depicted in FIG. 1 or is otherwise arranged to perform the operations discussed below.

Memory circuit 100 is an IC that includes memory partitions 102A-102D, a global control circuit 100GC and global input output (GIO) circuits 100BL.

Each memory partition 102A-102D includes memory banks 110U and 110L adjacent to a word line (WL) driver circuit 110AC and a local control circuit 110LC. Each memory bank 110U and 110L includes a memory cell array 110AR and a local input output (LIO) circuit 110BS.

A memory partition, e.g., a memory partition 102A-102D, is a portion of memory circuit 100 that includes a subset of memory devices (not shown in FIG. 1) and adjacent circuits configured to selectively access the subset of memory devices in program and read operations. In the FIG. 1 embodiment, memory circuit 100 includes a total of four partitions. In some embodiments, memory circuit 100 includes a total number of partitions greater or fewer than four.

GIO circuit 100BL is configured to control access to one or more electrical paths, e.g., bit lines, to each memory device of the corresponding memory bank 110U or 110L of each memory partition 102A-102D, e.g., by generating one or more bit line signals. In some embodiments, GIO circuit 100BL includes a global bit line driver circuit. In some embodiments, GIO circuit 100BL is coupled to each memory bank 110U and 110L by a corresponding global bit line (not shown).

Global control circuit 100GC is configured to control some or all of program and read operations on each memory partition 102A-102D, e.g., by generating and/or outputting one or more control and/or enable signals.

In some embodiments, global control circuit 100GC includes one or more analog circuits configured to interface with memory partitions 102A-102D, cause data to be programmed in one or more memory devices, and/or use data received from one or more memory devices in one or more circuit operations. In some embodiments, global control circuit 100GC includes one or more global address decoder or pre-decoder circuits configured to output one or more address signals to the WL driver circuit 110AC of each memory partition 102A-102D.

Each WL driver circuit 110AC is configured to generate word line signals on corresponding word lines WL. In some embodiments, each WL driver circuit 110AC is configured to output word line signals on corresponding word lines WL to the adjacent memory banks 110U and 110L of the corresponding memory partition 102A-102D.

Each local control circuit 110LC is an electronic circuit configured to receive one or more address signals. Each local control circuit 110LC is configured to generate signals corresponding to adjacent subsets of memory devices identified by the one or more address signals. In some embodiments, the adjacent subsets of memory devices correspond to columns of memory devices. In some embodiments, each local control circuit 110LC is configured to generate each signal as a complementary pair of signals. In some embodiments, each local control circuit 110LC is configured to output the signals to corresponding word line driver circuits within the adjacent WL driver circuit 110AC of the corresponding memory partition 102A-102D. In some embodiments, the local control circuit 110LC includes a bank decoder circuit.

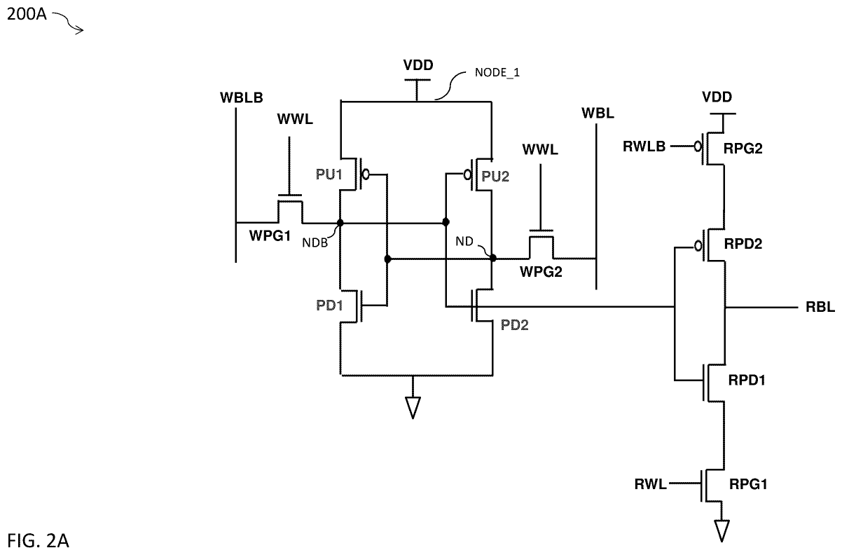

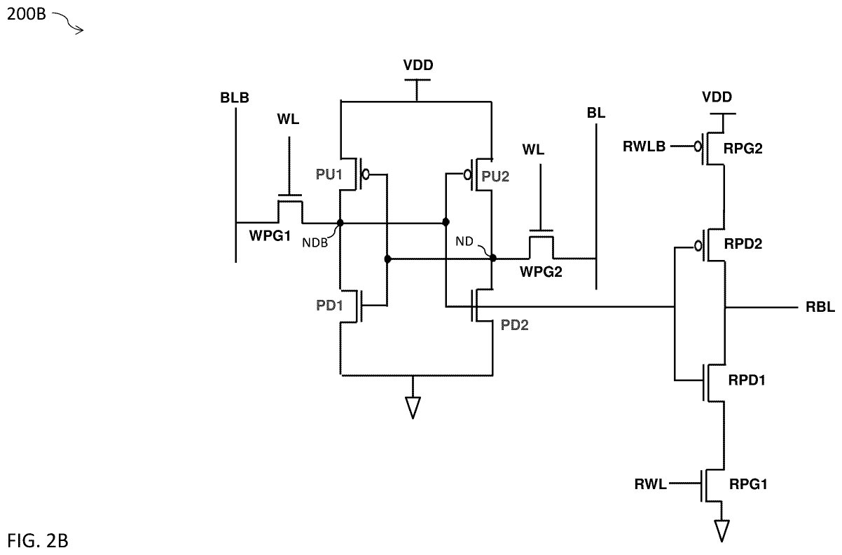

Each LIO circuit 110BS is configured to selectively access one or more bit lines (shown in FIG. 2) coupled to adjacent subsets of memory devices of the corresponding memory cell array 110AR responsive to GIO circuit 100BL, e.g., based on one or more BL control signals. In some embodiments, the adjacent subsets of memory devices correspond to rows of memory devices. In some embodiments, the LIO circuit 110BS includes a bit line selection circuit.

Each LIO circuit 110BS includes one or more circuits 114. For ease of illustration, circuit 114 is not shown in memory bank 110U and 110L of memory partitions 102B, 102C and 102D. In some embodiments, each circuit 114 includes at least a sense amplifier circuit. In some embodiments, during a read operation, the sense amplifier circuit is configured to read data from at least one memory cell 112 in a corresponding column of memory cells in the corresponding memory cell array 110AR, in accordance with some embodiments. In some embodiments, each circuit 114 in LIO circuit 110BS is coupled to a corresponding column of memory devices 112 in memory cell array 110AR.

Each memory bank 110U and 110L includes the corresponding memory cell array 110AR including memory cells or memory devices 112 configured to be accessed in program and read operations by the adjacent LIO circuit 110BS and the adjacent WL driver circuit 110AC.

Each memory cell array 110AR includes an array of memory devices 112 having N rows and M columns, where M and N are positive integers. The rows of cells in memory cell array 102 are arranged in a first direction X. The columns of cells in memory cell array 102 are arranged in a second direction Y. The second direction Y is different from the first direction X. In some embodiments, the second direction Y is perpendicular to the first direction X. In some embodiments, each memory cell array 110AR is divided into an upper region and a lower region (not shown). In some embodiments, each column of memory devices 112 in memory cell array 110AR is coupled to a corresponding circuit 114 in LIO circuit 110BS.

Memory device 112 is shown in memory bank 110U and 110L of memory partition 102A. For ease of illustration, memory device 112 is not shown in memory bank 110U and 110L of memory partitions 102B, 102C and 102D.

Memory device 112 is an electrical, electromechanical, electromagnetic, or other device configured to store bit data represented by logical states. At least one logical state of memory device 112 is capable of being programmed in a write operation and detected in a read operation. In some embodiments, a logical state corresponds to a voltage level of an electrical charge stored in a given memory device 112. In some embodiments, a logical state corresponds to a physical property, e.g., a voltage, a current, a resistance or a magnetic orientation, of a component of a given memory device 112.

In some embodiments, memory device 112 includes one or more multi-port static random access memory (SRAM) cells. In some embodiments, memory device 112 includes one or more dual port (DP) SRAM cells. In some embodiments, memory device 112 includes one or more single port (SP) SRAM cells. In some embodiments, memory device 112 includes the one or more SRAM cells include complementary FET (CFET) transistors. Different types of memory cells in memory device 112 are within the contemplated scope of the present disclosure. In some embodiments, memory device 112 includes one or more dynamic random access memory (DRAM) cells. In some embodiments, memory device 112 includes one or more one-time programmable (OTP) memory devices such as electronic fuse (eFuse) or anti-fuse devices, flash memory devices, random-access memory (RAM) devices, resistive RAM devices, ferroelectric RAM devices, magneto-resistive RAM devices, erasable programmable read only memory (EPROM) devices, electrically erasable programmable read only memory (EEPROM) devices, or the like. In some embodiments, memory device 112 is an OTP memory device including one or more OTP memory cells.

Other configurations of memory circuit 100 are within the scope of the present disclosure.

FIGS. 2A-2B are corresponding circuit diagrams of corresponding memory cells 200A and 200B usable in FIG. 1, in accordance with some embodiments.

FIG. 2A is a circuit diagram of a memory cell 200A usable in FIG. 1, in accordance with some embodiments.

At least one of memory cell 200A or 200B is usable as one or more memory cells MCB in at least one of memory cell array 110AR of FIG. 1 or memory device 112 of FIG. 1.

At least one of memory cell 200A or 200B is a ten transistor (10T) multi-port (MP) SRAM memory cell with a CMOS read port. In some embodiments, at least one of memory cell 200A or 200B employs a number of transistors other than ten. Other types of memory are within the scope of various embodiments. In some embodiments, a multi-port memory cell is a type of RAM that is configured to support multiple reads or writes occurring at the same time at different addresses within a memory cell array (e.g., memory cell array 110AR in FIG. 1). In some embodiments, a multi-port memory cell is configured to support corresponding multiple memory cell accesses (e.g., reads or writes) per clock cycle.

Memory cell 200A comprises P field effect transistors (PFET) PU1, PU2, RPD2 and RPG2, and NFET transistors PD1, PD2, WPG1, WPG2, RPD1 and RPG1. PFET transistors PU1 and PU2 and NFET transistors PD1 and PD2 form a cross latch or a pair of cross-coupled inverters. For example, PFET transistor PU1 and NFET transistor PD1 form a first inverter while PFET transistor PU2 and NFET transistor PD2 form a second inverter.

A source terminal of each of PFET transistors PU1 and PU2 is configured as a voltage supply node NODE_1. Each voltage supply node NODE_1 is coupled to a first voltage supply VDD.

Each of a drain terminal of PFET transistor PU1, a drain terminal of NFET transistor PD1, a gate terminal of PFET transistor PU2, a gate terminal of NFET transistor PD2, a source terminal of NFET transistor WPG1, a gate terminal of PFET transistor RPD2 and a gate terminal of NFET transistor RPD1 are coupled together, and are configured as a storage node NDB.

Each of a drain terminal of PFET transistor PU2, a drain terminal of NFET transistor PD2, a gate terminal of PFET transistor PU1, a gate terminal of NFET transistor PD1 and a source terminal of NFET transistor WPG2 are coupled together, and are configured as a storage node ND.

A source terminal of each of NFET transistors PD1 and PD2 is configured as a supply reference voltage node (not labelled) having a supply reference voltage VSS. The source terminal of each of NFET transistors PD1 and PD2 is also coupled to reference voltage supply VSS.

A write word line WWL is coupled with a gate terminal of each of NFET transistors WPG1 and WPG2. Write word line WWL is also called a write control line because NFET transistors WPG1 and WPG2 are configured to be controlled by a signal on write word line WWL in order to transfer data between write bit line bar WBLB/write bit line WBL and corresponding node NDB/ND.

In some embodiments, the signal of the write word line WWL is equal to a voltage supply VDD. In some embodiments, when the signal of the write word line WWL is equal to the voltage supply VDD, the NFET transistors WPG1 and WPG1 are turned on.

A drain terminal of NFET transistor WPG1 is coupled to a write bit line bar WBLB. A drain terminal of NFET transistor WPG2 is coupled to a write bit line WBL.

Write bit line bar WBLB and the write bit line WBL are configured as data input for memory cell 200A.

A source terminal of PFET transistor RPG2 is coupled to the first voltage supply VDD.

A gate terminal of PFET transistor RPG2 is coupled to a read word line bar RWLB. In some embodiments, the gate terminal of PFET transistor RPG2 is configured to receive a read word line bar signal from the read word line bar RWLB. Each of a drain terminal of PFET transistor RPG2 and a source terminal of PFET transistor RPD2 are coupled together.

Each of a drain terminal of PFET transistor RPD2 and a drain terminal of NFET transistor RPD1 are coupled together, and are further coupled to a read bit line RBL. In some embodiments, the drain terminal of PFET transistor RPD2 and the drain terminal of NFET transistor RPD1 are configured to generate the read bit line signal RBL. In some embodiments, the drain terminal of PFET transistor RPD2 and the drain terminal of NFET transistor RPD1 are configured to output the read bit line signal RBL to the read bit line RBL.

Each of the gate terminal of NFET transistor RPD1 and the gate terminal of PFET transistor RPD2 are coupled to the storage node NDB. In some embodiments, each of the gate terminal of NFET transistor RPD1 and the gate terminal of PFET transistor RPD2 are configured to receive the data stored in node NDB or ND.

A gate terminal of NFET transistor RPG1 is coupled to a read word line RWL. In some embodiments, the gate terminal of NFET transistor RPG1 is configured to receive a read word line signal from the read word line RWL. Each of a drain terminal of NFET transistor RPG1 and a source terminal of NFET transistor RPD1 are coupled together.

A source terminal of NFET transistor RPG1 is coupled to the reference supply voltage VSS.

In some embodiments, NFET transistor RPD1, NFET transistor RPG1, PFET transistor RPD2, PFET transistor RPG2 are configured to read the data stored in memory cell 200A at node ND or NDB.

Read bit line RBL is configured to output data stored in memory cell 200A.

In some embodiments, in a read operation, applying a logical value to the read word line bar RWLB and the opposite logical value to the read word line RWL enables reading the logical values stored at nodes ND or NDB from memory cell 200A-200B by the read bit line RBL.

In some embodiments, in a write operation, applying a logical value to the write bit line bar WBLB and the opposite logical value to the write bit line WBL enables writing the logical values on the write bit lines to memory cell 200A-200B.

Other configurations of memory cell 200A are within the scope of the present disclosure.

FIG. 2B is a circuit diagram of a memory cell 200B usable in FIG. 1, in accordance with some embodiments.

Memory cell 200B is a variation of memory cell 200A of FIG. 2A, and similar detailed description is therefore omitted. In comparison with memory cell 200A of FIG. 2A, a word line WL in FIG. 2B replaces the corresponding write word lines WWL in FIG. 2A, a bit line BL in FIG. 2B replaces the corresponding write bit line WBL in FIG. 2A, and a bit line bar BLB in FIG. 2B replaces the corresponding write bit line bar WBLB in FIG. 2A, and similar detailed description is therefore omitted.

Other configurations of memory cell 200B are within the scope of the present disclosure.

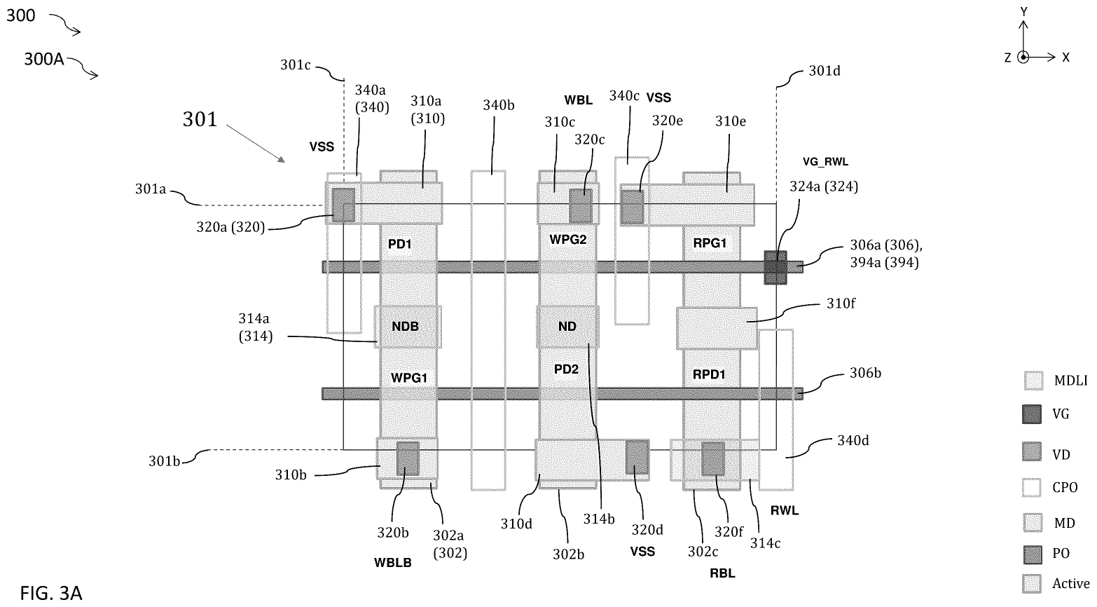

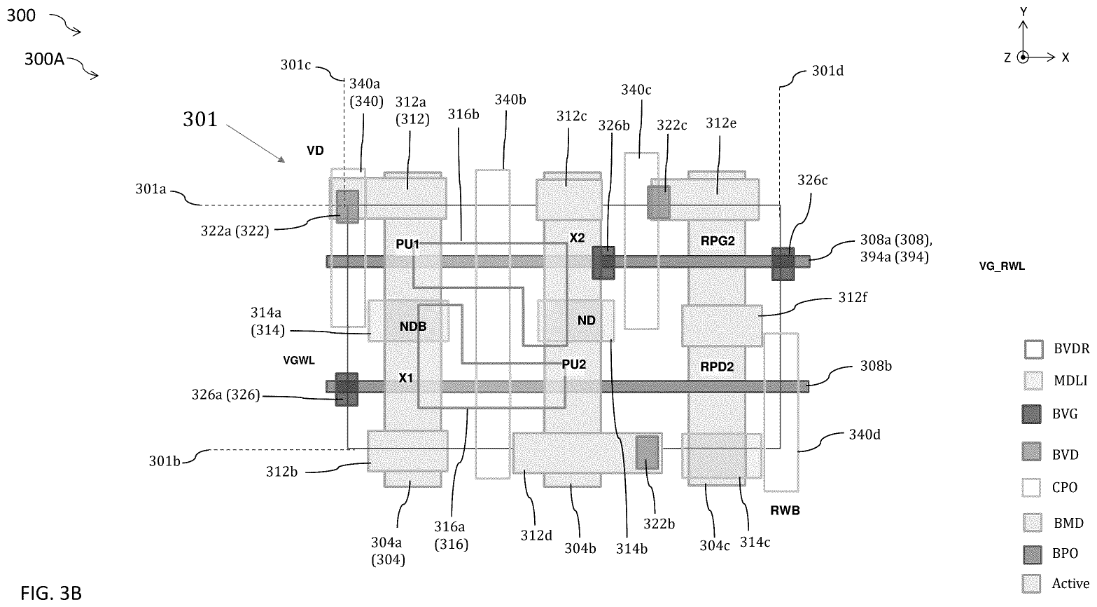

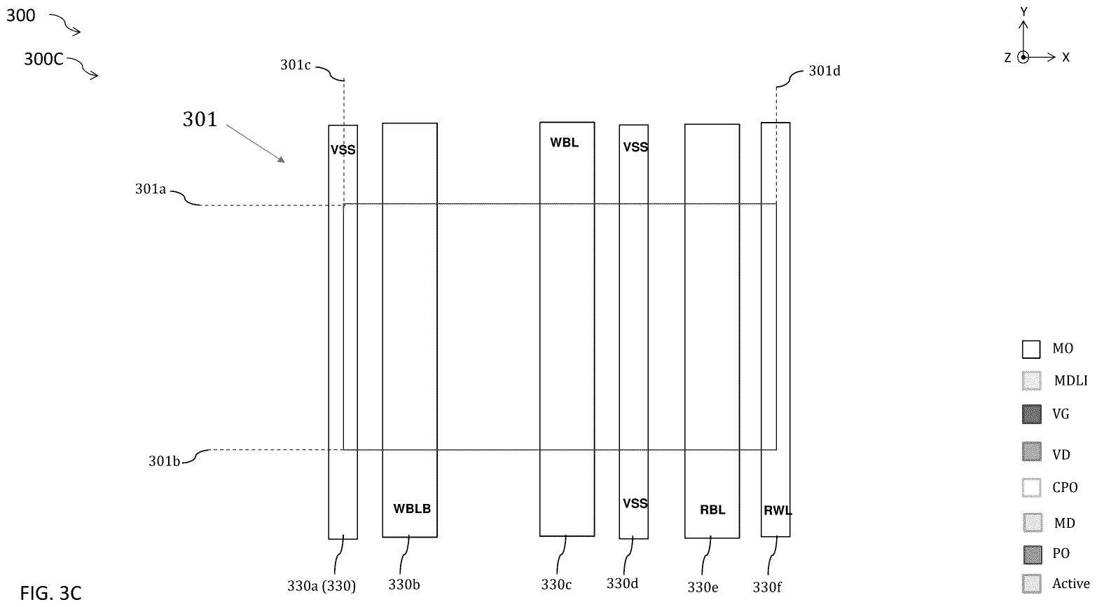

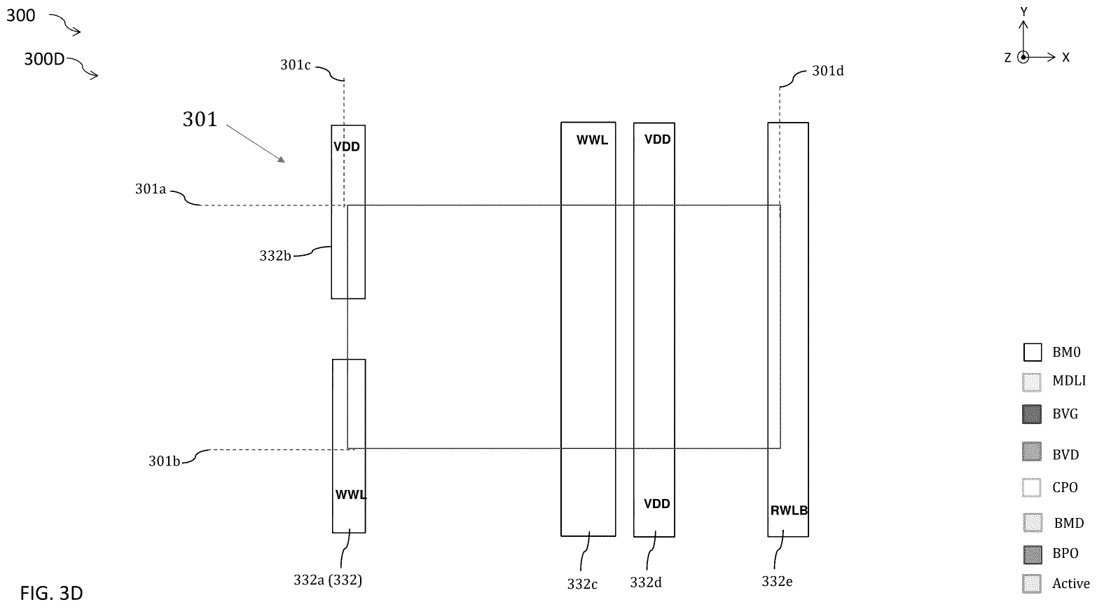

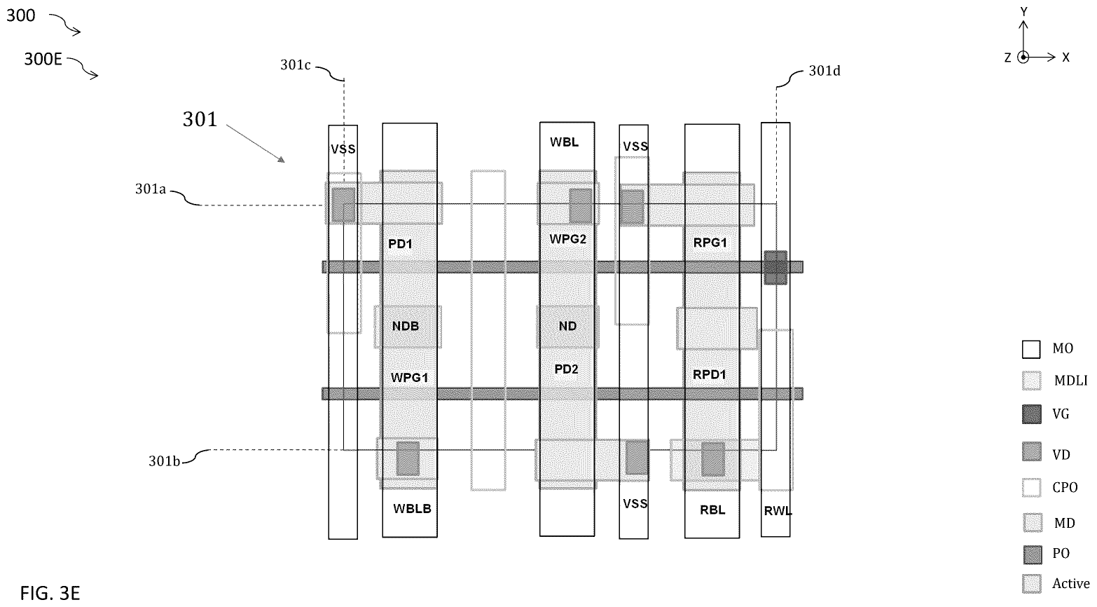

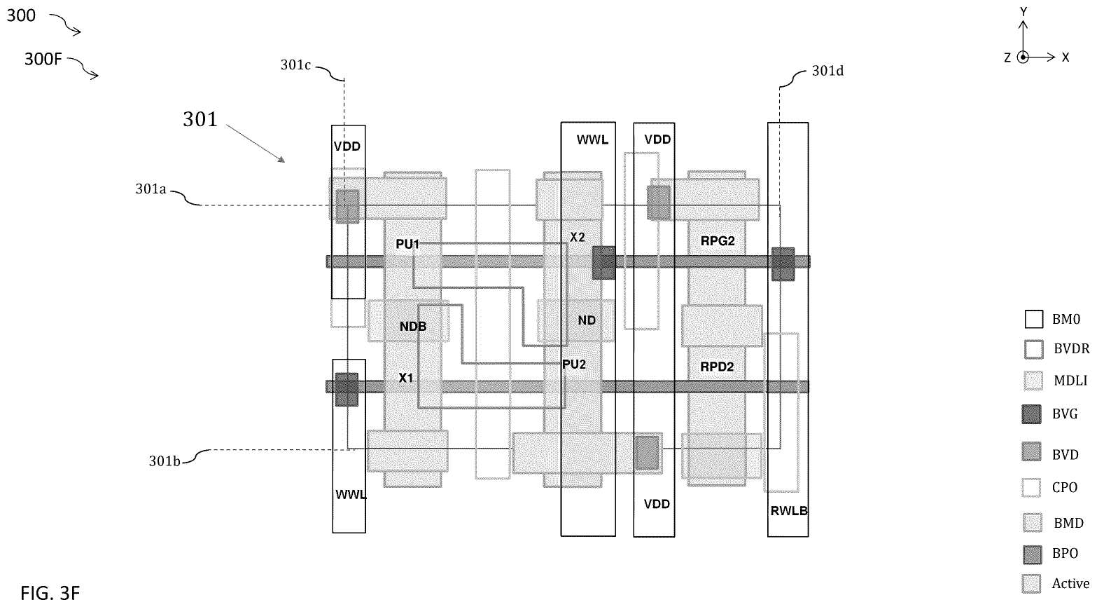

FIGS. 3A-3F are corresponding diagrams of corresponding portions 300A-300F of a layout design 300 of a corresponding integrated circuit, in accordance with some embodiments.

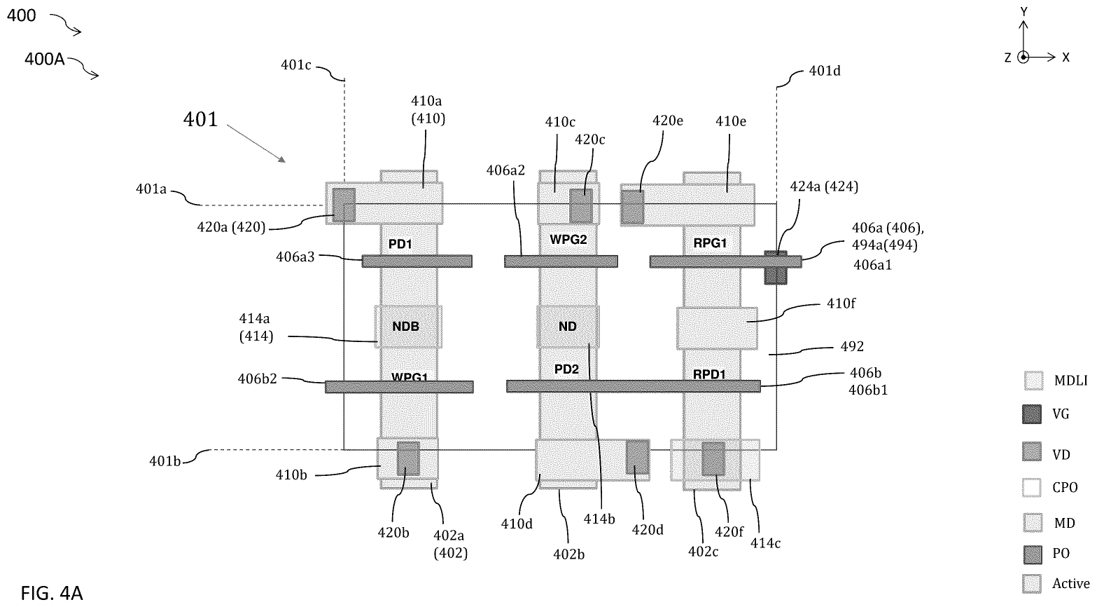

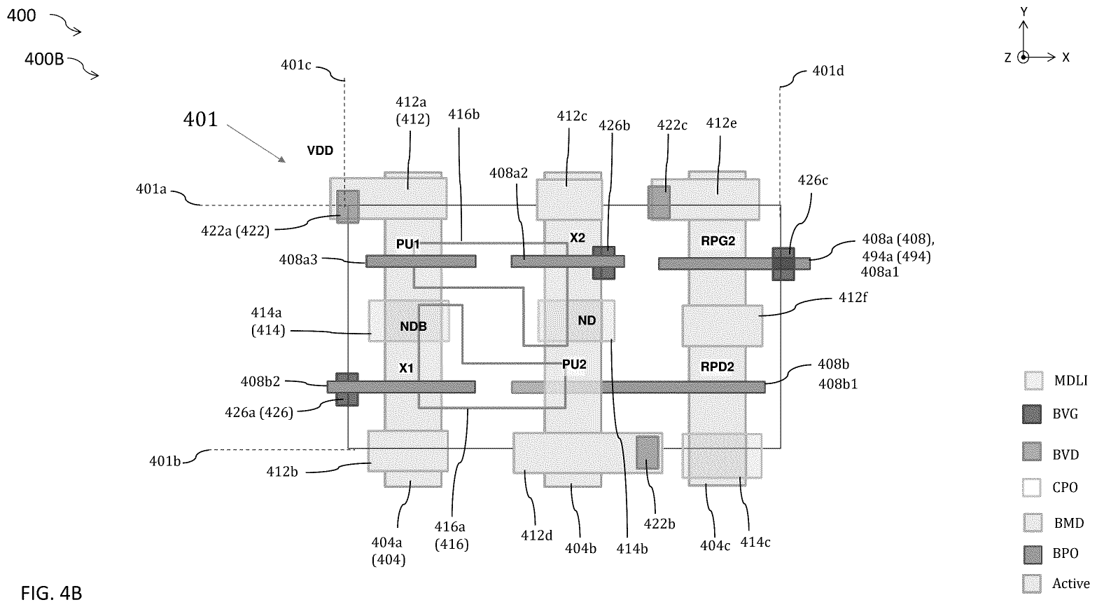

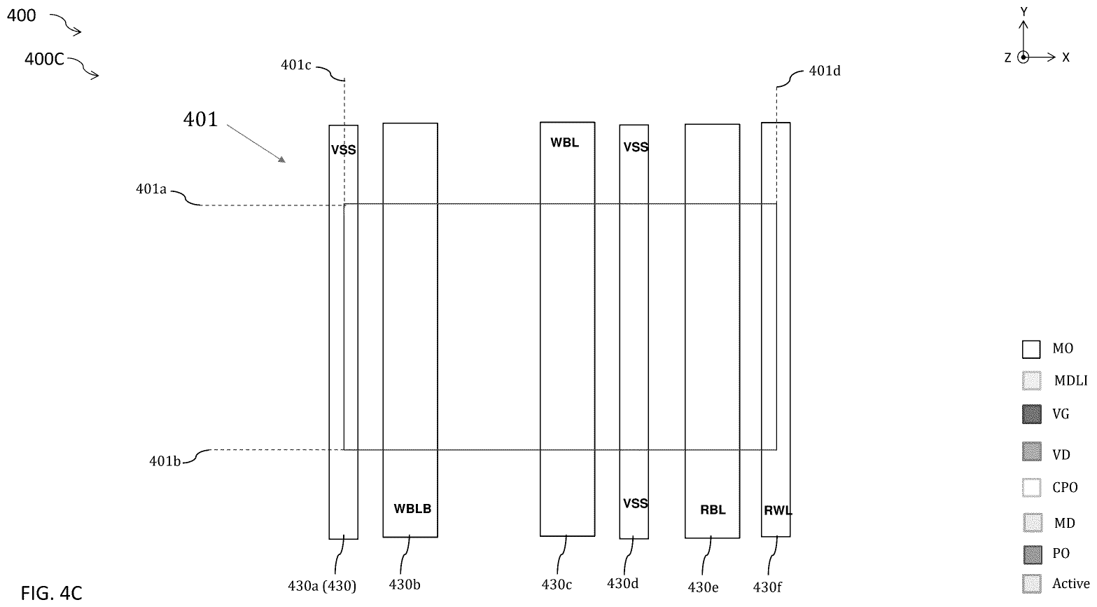

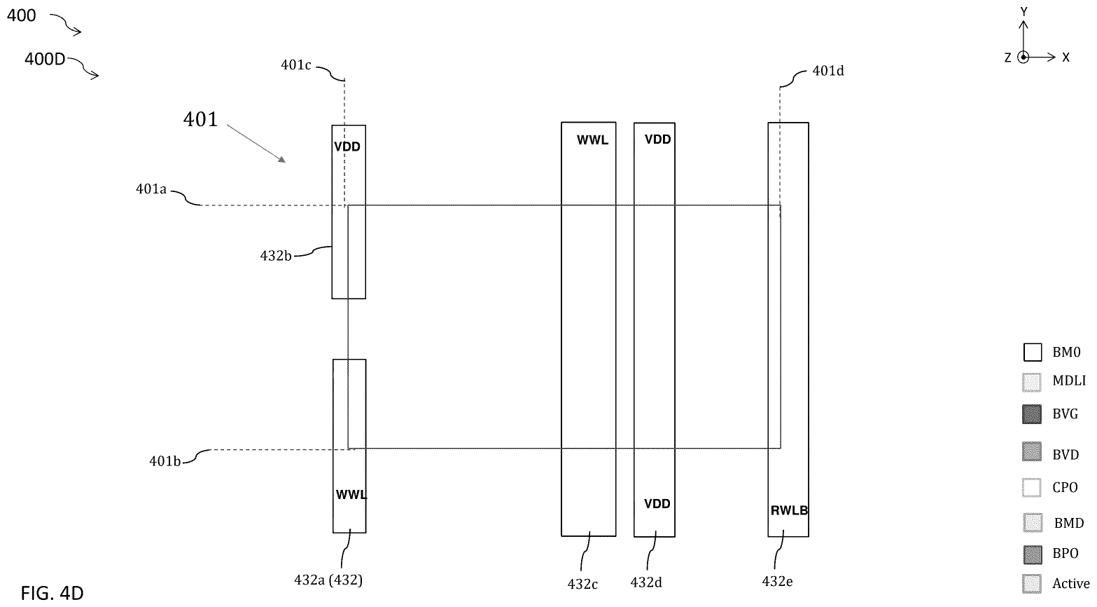

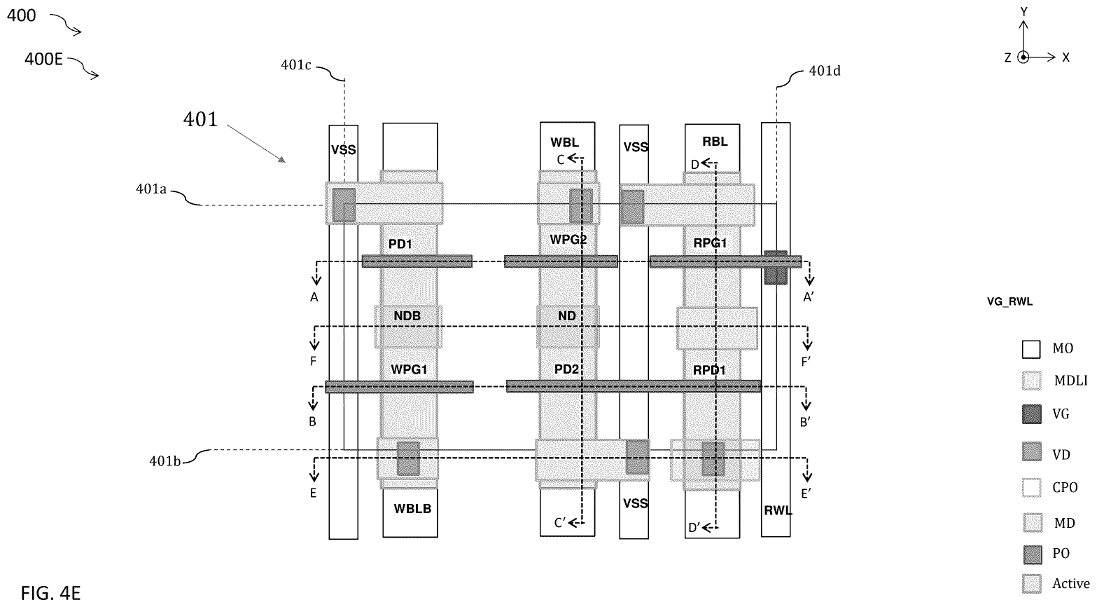

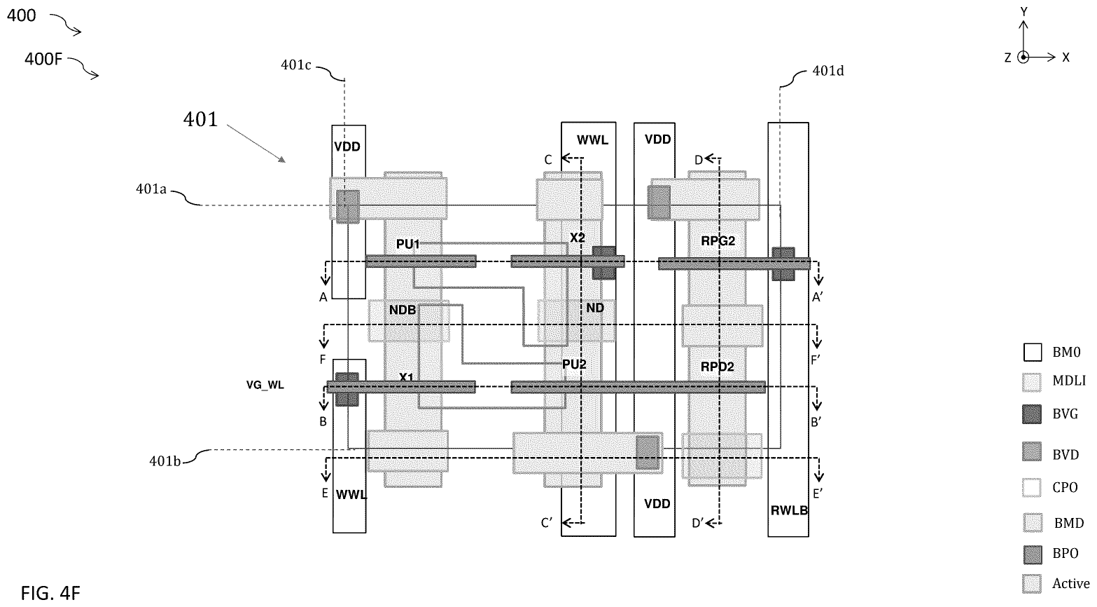

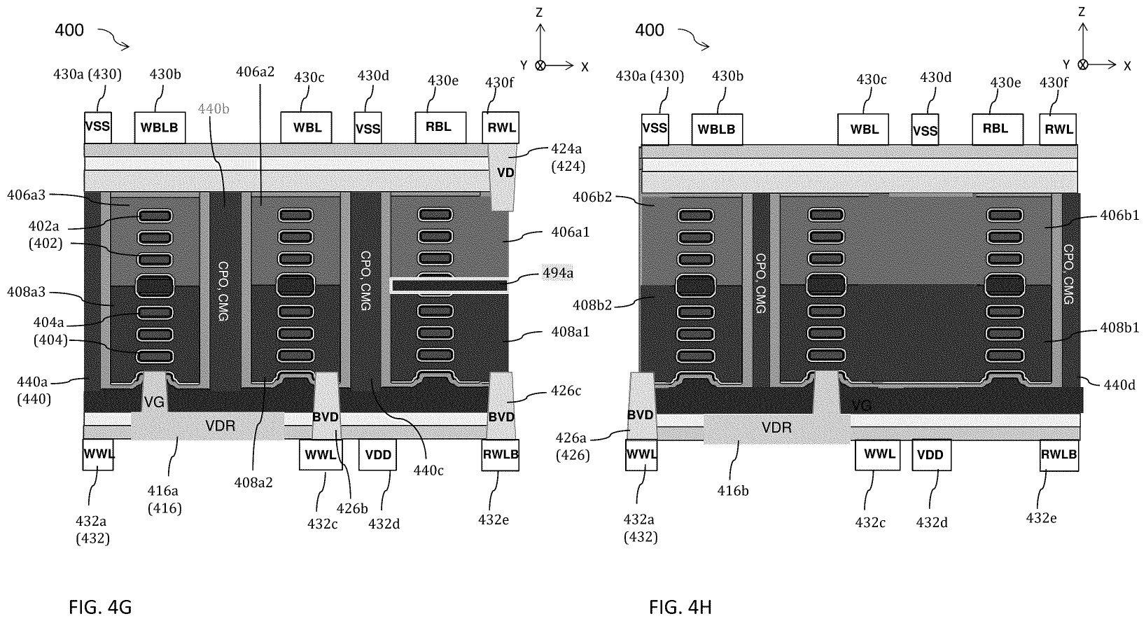

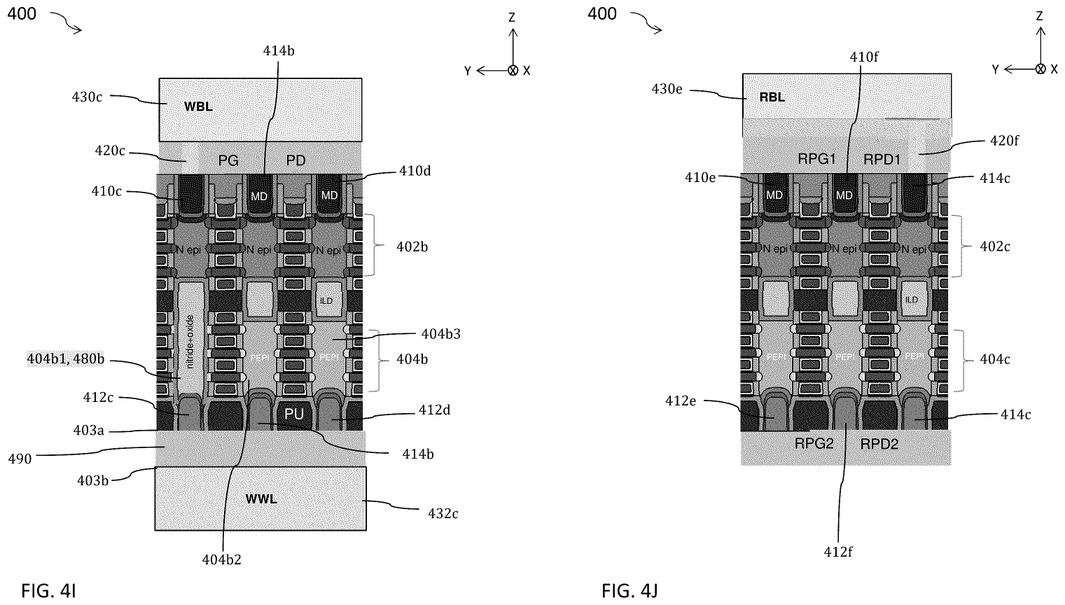

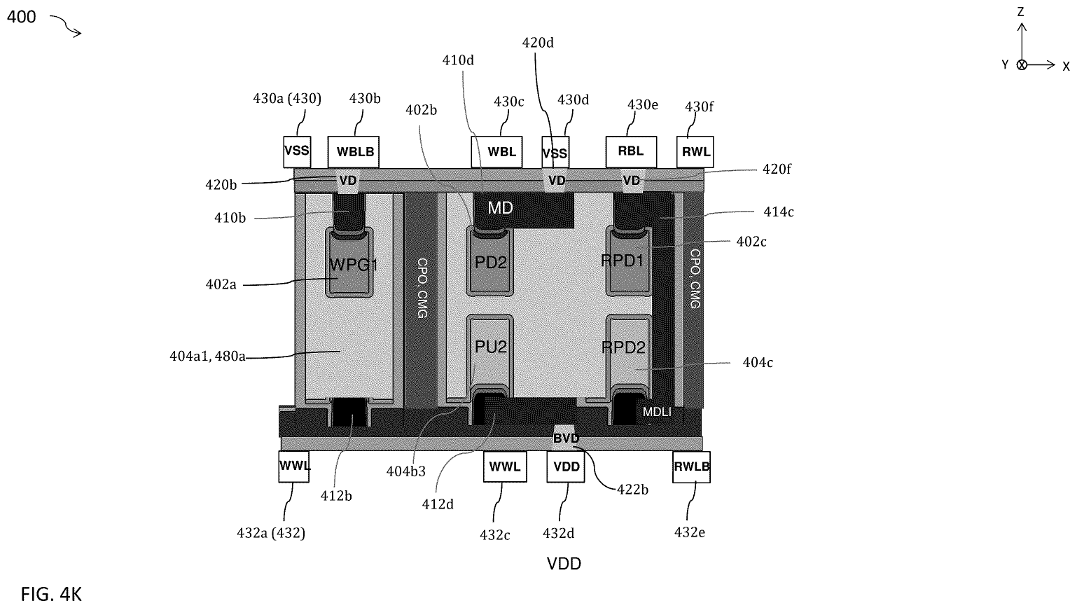

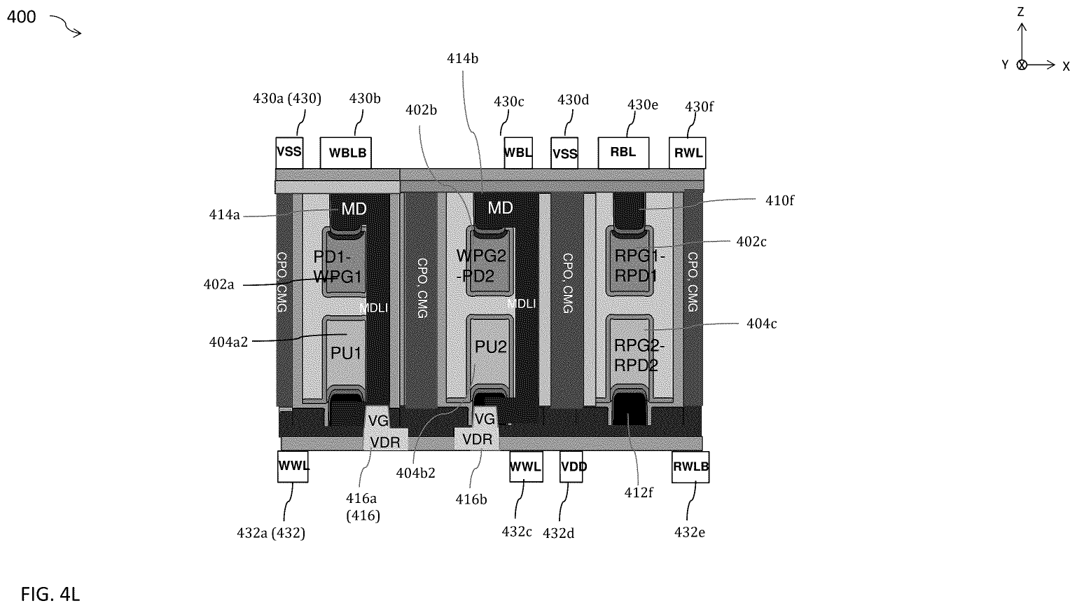

Layout design 300 is a layout of an integrated circuit 400 of FIGS. 4A-4L or memory cell 200A. Layout design 300 is a layout of memory cell 200A of FIG. 2A.

Portion 300A includes one or more features of layout design 300 of an active level or an oxide diffusion (OD) level, a gate (POLY or PO) level, a cut gate or cut POLY (CPOLY or CPO) level, a metal over diffusion (MD) level, a metal over diffusion local interconnect (MDLI) level, a via over gate (VG) level, and a via over diffusion (VD) level.

Portion 300B includes one or more features of layout design 300 of the OD level, the POLY level, the CPO level, a backside metal over diffusion (BMD) level, the MDLI level, a via to MD power rail (VDR) level, a backside via over gate (BVG) level, and a backside via over diffusion (BVD) level.

Portion 300C includes one or more features of layout design 300 of a metal 0 (M0) level.

Portion 300D includes one or more features of layout design 300 of a back-side metal 0 (BM0) level.

Portion 300E includes one or more features of layout design 300 of the OD level, the POLY level, the CPO level, the MD level, the MDLI level, the VG level, the VD level and the M0 level.

Portion 300F include one or more features of layout design 300 of the OD level, the POLY level, the CPO level, the BMD level, the MDLI level, the VDR level, the BVG level, the BVD level and the BM0 level.

FIGS. 3A-3F are corresponding diagrams of corresponding portions 300A-300F of layout design 300, simplified for ease of illustration.

For ease of illustration, some of the labeled elements of one or more of FIGS. 1-6B are not labelled in one or more of FIGS. 1-6B. In some embodiments, layout design 300 includes additional elements not shown in FIGS. 3A-3F. Layout design 300 includes one or more features of the OD level, the POLY level, the CPO level, the MD level, the MDLI level, the VG level, the VD level, the M0 level, the BMD level, the VDR level, the BVG level, the BVD level and the BM0 level.

In some embodiments, at least layout design 300, or integrated circuit 400 or 500 includes additional elements not shown in FIGS. 3A-3F, 4A-4L or 5A-5E.

Layout design 300 is usable to manufacture integrated circuit 400 of FIGS. 4A-4L.

Portion 300A is a layout of portion 400A of integrated circuit 400 of FIG. 4A, portion 300B is a layout of portion 400B of integrated circuit 400 of FIG. 4B, portion 300C is a layout of portion 400C of integrated circuit 400 of FIG. 4C, portion 300D is a layout of portion 400D of integrated circuit 400 of FIG. 4D, portion 300E is a layout of portion 400E of integrated circuit 400 of FIG. 4E, portion 300F is a layout of portion 400F of integrated circuit 400 of FIG. 4F, and similar detailed description is omitted for brevity.

Layout design 300 includes a cell 301. The cell 301 has cell boundaries 301a and 301b that extend in a first direction X, and cell boundaries 301c and 301d that extend in a second direction Y. In some embodiments, at least one of the first direction X, the second direction Y or a third direction Z is different from another of the first direction X, the second direction Y or the third direction Z. In some embodiments, layout design 300 abuts other cell layout designs (not shown) along cell boundaries 301c and 301d. In some embodiments, layout design 300 abuts other cell layout designs (not shown) along cell boundaries 301a and 301b that extend in the first direction X. In some embodiments, layout design 300 is a single height standard cell. In some embodiments, cell 301 is useable to manufacture a cell 401.

In some embodiments, cell 301 is a standard cell, and layout design 300 corresponds to a layout of a standard cell defined by cell boundaries 301a, 301b, 301c and 301d. In some embodiments, a cell 301 is a predefined portion of layout design 300 including one or more transistors and electrical connections configured to perform one or more circuit functions. In some embodiments, cell 301 is bounded by cell boundaries 301a, 301b, 301c and 301d, and thus corresponds to a region of functional circuit components or devices that are part of a standard cell. In some embodiments, layout design 300 is a layout design of a memory cell, such as memory cell 200A of FIG. 2A or 200B of FIG. 2B.

Layout design 300 includes one or more active region layout patterns 302a, 302b or 302c (collectively referred to as a “set of active region patterns 302”) or one or more active region layout patterns 304a, 304b or 304c (collectively referred to as a “set of active region patterns 304”) extending in the second direction Y.

Embodiments of the present disclosure use the term “layout pattern” which is hereinafter also referred to as “patterns” in the remainder of the present disclosure for brevity.

The set of active region patterns 302 is above the set of active region patterns 304.

Active region patterns 302a, 302b and 302c of the set of active region patterns 302 are separated from one another in the first direction X. Active region patterns 304a, 304b and 304c of the set of active region patterns 304 are separated from one another in the first direction X.

Active region patterns 302a and 304a are separated from one another in a third direction Z. Active region patterns 302b and 304b are separated from one another in the third direction Z. Active region patterns 302c and 304c are separated from one another in the third direction Z.

The set of active region patterns 302 is usable to manufacture a corresponding set of active regions 402 of integrated circuit 100, 200A, 200B, 400 or 500. The set of active region patterns 304 is usable to manufacture a corresponding set of active regions 404 of integrated circuit 100, 200A, 200B, 400 or 500.

In some embodiments, at least one of the set of active regions 402 or 404 are located on the front-side 403a of integrated circuit 100, 200A, 200B, 400 or 500. In some embodiments, at least one of the set of active regions 402 or 404 corresponds to source and drain regions of one or more complementary FET (CFET) transistors. In some embodiments, at least one of the set of active regions 402 or 404 correspond to source and drain regions of one or more nanosheet transistors or nanowire transistors. Other transistor types are within the scope of the present disclosure. In some embodiments, at least one of the set of active regions 402 or 404 corresponds to source and drain regions of one or more finFET transistors.

In some embodiments, active region patterns 302a, 302b, 302c are usable to manufacture corresponding active regions 402a, 402b, 402c of the set of active regions 402 of integrated circuit 100, 200A, 200B, 400 or 500. In some embodiments, active region patterns 304a, 304b, 304c are usable to manufacture corresponding active regions 404a, 404b, 404c of the set of active regions 404 of integrated circuit 100, 200A, 200B, 400 or 500.

In some embodiments, the set of active region patterns 302 and 304 are referred to as an oxide diffusion (OD) region which defines the source or drain diffusion regions of at least integrated circuit 100, 200A, 200B, 400 or 500 or layout design 300.

In some embodiments, active region patterns 302a, 302b and 302c are usable to manufacture source and drain regions of NFET transistors of integrated circuits 100, 200A, 200B, 400 or 500, and active region patterns 304a, 304b and 304c are usable to manufacture source and drain regions of PFET transistors of integrated circuits 100, 200A, 200B, 400 or 500.

In some embodiments, active region patterns 302a, 302b and 302c are usable to manufacture source and drain regions of PFET transistors of integrated circuits 100, 200A, 200B, 400 or 500, and active region patterns 304a, 304b and 304c are usable to manufacture source and drain regions of NFET transistors of integrated circuits 100, 200A, 200B, 400 or 500.

In some embodiments, the set of active region patterns 302 or 304 is located on a first layout level. In some embodiments, the first layout level corresponds to an active level or an OD level of one or more of layout design 300 or integrated circuits 100, 200A, 200B, 400 or 500. In some embodiments, the OD level is above at least the BM0.

Other configurations, arrangements on other layout levels or quantities of patterns in the set of active region patterns 302 or 304 are within the scope of the present disclosure.

Layout design 300 further includes one or more gate patterns 306a or 306b (collectively referred to as a “set of gate patterns 306”), one or more gate patterns 308a or 308b (collectively referred to as a “set of gate patterns 308”) extending in the first direction X.

The set of gate patterns 306 is above the set of gate patterns 308.

In some embodiments, gate patterns 306a and 308a are separated from one another in the third direction Z. In some embodiments, gate patterns 306b and 308b are separated from one another in the third direction Z.

The set of gate patterns 306 is usable to manufacture a corresponding set of gates 406 of integrated circuit 100, 200A, 200B, 400 or 500. The set of gate patterns 308 is usable to manufacture a corresponding set of gates 408 of integrated circuit 100, 200A, 200B, 400 or 500.

In some embodiments, gate patterns 306a or 306b are usable to manufacture corresponding gates 406a or 406b of the set of gates 406 of integrated circuit 100, 200A, 200B, 400 or 500. In some embodiments, gate patterns 308a or 308b are usable to manufacture corresponding gates 408a or 408b of the set of gates 408 of integrated circuit 100, 200A, 200B, 400 or 500.

In some embodiments, at least one of the set of gates 406 or 408 are located on the front-side 403a of integrated circuit 100, 200A, 200B, 400 or 500.

In some embodiments, each of the gate patterns in the set of gate patterns 306 and 308 is shown in FIGS. 3A-3F with labels “PD1, PU1, PD2, PU2, WPG1, WPG2, RPD1, RPD2, RPG1, RPG2, X1, X2” that identify corresponding transistors of FIGS. 2A-2B manufactured by the corresponding gate pattern in FIGS. 3A-3F, and are omitted for brevity.

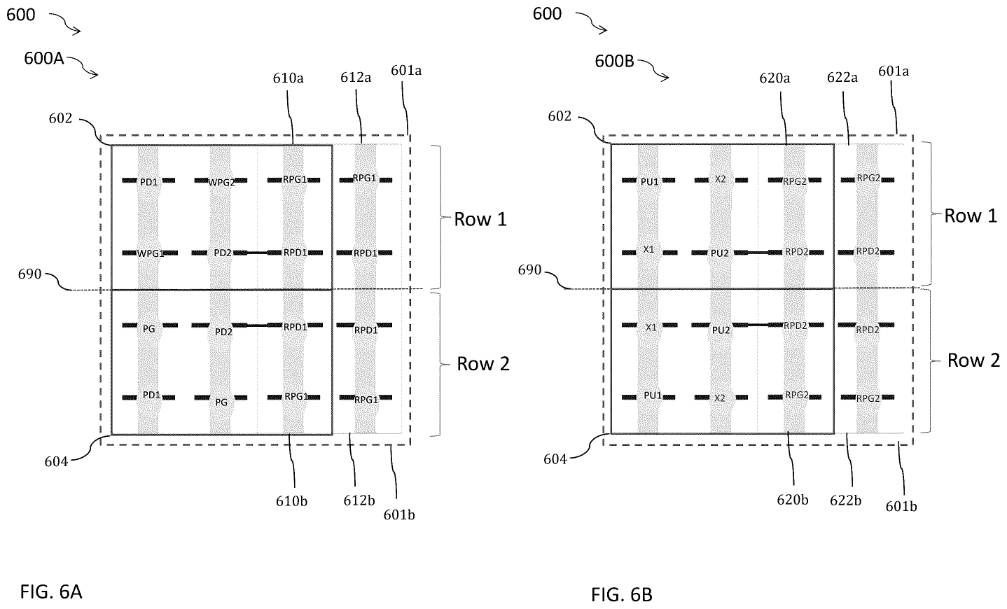

In some embodiments, at least one of label X1 or X2 is a corresponding dummy transistor on the back-side of layout design 300. In some embodiments, at least one of label X1 or X2 is the corresponding dummy transistor shown in integrated circuit 600B of FIG. 6B. In some embodiments, a dummy transistor is a non-functional transistor. In some embodiments, a dummy transistor is a transistor where the source and/or drain is replaced with a corresponding insulating region, such as insulating region 480a in FIG. 4I.

In some embodiments, the set of gate patterns 306 or 308 encapsulate the set of active region patterns 302 and 304. In some embodiments, at least a portion of the set of gate patterns 306 or 308 is above the set of active region patterns 302 and 304. In some embodiments, at least another portion of the set of gate patterns 306 or 308 is below the set of active region patterns 302 and 304.

The set of gate patterns 306 or 308 is positioned on a second layout level. In some embodiments, the second layout level is different from the first layout level. In some embodiments, the second layout level corresponds to the POLY level (also referred to as PO level or MG level) of one or more of layout design 300 or integrated circuits 100, 200A, 200B, 400 or 500. In some embodiments, the POLY level is above the BMD and the BM0 level.

Other configurations, arrangements on other layout levels or quantities of patterns in the set of gate patterns 306 or 308 are within the scope of the present disclosure.

Layout design 300 further includes one or more cut feature patterns 340a, 340b, 340c or 340d (collectively referred to as a “set of cut feature patterns 340”) extending in the second direction Y.

The set of cut feature patterns 340 is above the set of gate patterns 306 or 308.

At least one of cut feature pattern 340a, 340b, 340c or 340d is separated from another of cut feature pattern 340a, 340b, 340c or 340d in at least one of the first direction X or the second direction Y.

In some embodiments, the set of cut feature patterns 340 overlap at least a portion of a gate pattern of the set of gate patterns 306 or 308. In some embodiments, the set of cut feature patterns 340 overlaps other underlying patterns (not shown) of other layout levels (e.g., BM0, BMD, Active, MD, or the like) of layout design 300.

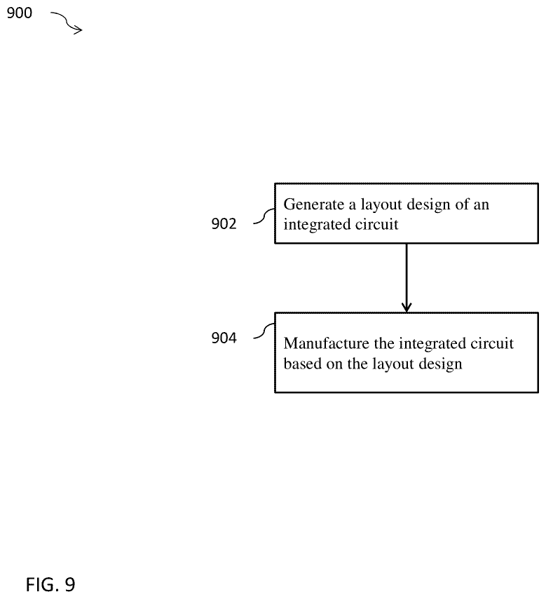

In some embodiments, cut feature patterns 340a, 340b, 340c or 340d identify corresponding locations of corresponding removed gate portions 440a, 440b, 440c or 440d of the set of removed gate portions 440 that are removed in operation 904 of method 900 (FIG. 9).

In some embodiments, cut feature pattern 340b is usable to separate gate 406a3 and gate 406a2 from each other. In some embodiments, cut feature pattern 340b is usable to separate gate 408a3 and gate 408a2 from each other.

In some embodiments, cut feature pattern 340b is usable to separate gate 406b2 and gate 406b1 from each other. In some embodiments, cut feature pattern 340b is usable to separate gate 408b2 and gate 408b1 from each other.

In some embodiments, cut feature pattern 340c is usable to separate gate 406a2 and gate 406a1 from each other. In some embodiments, cut feature pattern 340c is usable to separate gate 408a2 and gate 408a1 from each other.

Other configurations, arrangements on other layout levels or quantities of patterns in the set of cut feature patterns 340 are within the scope of the present disclosure. In some embodiments, at least one cut feature pattern of the set of cut feature patterns 340 is not included in layout design 300.

The set of cut feature patterns 340 is positioned on the second layout level.

Other configurations, arrangements on other layout levels or quantities of patterns in the set of cut feature patterns 340 are within the scope of the present disclosure.

Layout design 300 further includes one or more insulating region patterns 394a (collectively referred to as a “set of insulating region patterns 394”) extending in the second direction Y.

In some embodiments, the set of insulating region patterns 394 is between the set of gate patterns 306 and the set of gate patterns 308. In some embodiments, the set of insulating region patterns 394 is above the set of gate patterns 308. In some embodiments, the set of insulating region patterns 394 is below the set of gate patterns 306.

In some embodiments, gate pattern 306a and gate pattern 308a are separated from each other in the third direction Z by the insulating region pattern 394a of the set of insulating region patterns 394. In some embodiments, a portion 306a1 of gate pattern 306a and a portion 308a1 of gate pattern 308a are separated from each other in the third direction Z by the insulating region pattern 394a of the set of insulating region patterns 394.

The set of insulating region patterns 394 is usable to manufacture a corresponding set of insulating regions 494 of integrated circuit 100, 200A, 200B, 400 or 500. The set of insulating region patterns 394 is usable to manufacture a corresponding set of insulating region patterns 494a of integrated circuit 100, 200A, 200B, 400 or 500.

Other configurations, arrangements on other layout levels or other numbers of portions in insulating region pattern 394 are within the scope of the present disclosure.

Layout design 300 further includes one or more contact patterns 310a, 310b, 310c, 310d, 310e, 310f (collectively referred to as a “set of contact patterns 310”) extending in the first direction X.

Each of the contact patterns of the set of contact patterns 310 is separated from an adjacent contact pattern of the set of contact patterns 310 in at least the first direction X or the second direction Y.

The set of contact patterns 310 is usable to manufacture a corresponding set of contacts 410 of integrated circuit 100, 200A, 200B, 400 or 500.

In some embodiments, contact pattern 310a, 310b, 310c, 310d, 310e, 310f of the set of contact patterns 310 is usable to manufacture corresponding contact 410a, 410b, 410c, 410d, 410e, 410f of the set of contact patterns 410. In some embodiments, the set of contact patterns 310 is also referred to as a set of metal over diffusion (MD) patterns.

In some embodiments, at least one of contact pattern 310a, 310b, 310c, 310d, 310e, 310f of the set of contact patterns 310 is usable to manufacture source or drain terminals of the NFET of integrated circuit 100, 200A, 200B, 400 or 500.

In some embodiments, at least one of contact pattern 310a, 310b, 310c, 310d, 310e, 310f of the set of contact patterns 310 is usable to manufacture source or drain terminals of the PFET transistors of integrated circuit 100, 200A, 200B, 400 or 500.

In some embodiments, contact pattern 310a is usable to manufacture source/drain terminals of NFET transistor PD1, contact pattern 310b is usable to manufacture source/drain terminals of NFET transistor WPG1, contact pattern 310c is usable to manufacture source/drain terminals of NFET transistor WPG2, contact pattern 310d is usable to manufacture source/drain terminals of NFET transistor PD2, contact pattern 310e is usable to manufacture source/drain terminals of NFET transistor RPG1, and contact pattern 310f is usable to manufacture drain/source terminals of NFET transistor RPG1, and source/drain terminals of NFET transistor RPD1.

In some embodiments, the set of contact patterns 310 overlaps the set of active region patterns 302 or 304. The set of contact patterns 310 is located on a third layout level. In some embodiments, the third layout level corresponds to the contact level or an MD level of one or more of layout design 300 or integrated circuits 100, 200A, 200B, 400 or 500. In some embodiments, the third layout level is different from at least one of the first layout level or the second layout level. Other configurations, arrangements on other layout levels or quantities of patterns in the set of contact patterns 310 are within the scope of the present disclosure.

Layout design 300 further includes one or more contact patterns 312a, 312b, 312c, 312d, 312e, 312f (collectively referred to as a “set of contact patterns 312”) extending in the first direction X.

Each of the contact patterns of the set of contact patterns 312 is separated from an adjacent contact pattern of the set of contact patterns 312 in at least the first direction X or the second direction Y.

The set of contact patterns 310 and 312 are separated from one another in the third direction Z. In some embodiments, contact patterns 310a and 312a are separated from one another in the third direction Z. In some embodiments, contact patterns 310b and 312b are separated from one another in the third direction Z. In some embodiments, contact patterns 310c and 312c are separated from one another in the third direction Z. In some embodiments, contact patterns 310d and 312d are separated from one another in the third direction Z. In some embodiments, contact patterns 310e and 312e are separated from one another in the third direction Z. In some embodiments, contact patterns 310f and 312f are separated from one another in the third direction Z.

The set of contact patterns 312 is usable to manufacture a corresponding set of contacts 412 of integrated circuit 100, 200A, 200B, 400 or 500.

In some embodiments, contact pattern 312a, 312b, 312c, 312d, 312e, 312f of the set of contact patterns 312 is usable to manufacture corresponding contact 412a, 412b, 412c, 412d, 412e, 412f of the set of contacts 412. In some embodiments, the set of contacts 412 are on a back-side 403b of integrated circuit 400. In some embodiments, the back-side 403b of integrated circuit 400 is opposite from the front-side of integrated circuit 400. In some embodiments, the set of contacts patterns 312 is also referred to as a set of back-side MD (BMD) patterns.

In some embodiments, contact pattern 312a is usable to manufacture source/drain terminals of PFET transistor PU1, contact pattern 312b is usable to manufacture source/drain terminals of PFET transistor X1, contact pattern 312c is usable to manufacture source/drain terminals of PFET transistor X2, contact pattern 312d is usable to manufacture source/drain terminals of PFET transistor PU2, contact pattern 312e is usable to manufacture source/drain terminals of PFET transistor RPG2, and contact pattern 312f is usable to manufacture drain/source terminals of PFET transistor RPG2, and source/drain terminals of PFET transistor RPD2.

In some embodiments, at least one of PFET transistor X1 or PFET transistor X2 is a corresponding dummy transistor.

In some embodiments, the set of contact patterns 312 are overlapped by the set of active region patterns 302 or 304. The set of contact patterns 312 is located on a fourth layout level. In some embodiments, the fourth layout level corresponds to the back-side contact level or a back-side MD (BMD) level of one or more of layout design 300 or integrated circuits 100, 200A, 200B, 400 or 500. In some embodiments, the fourth layout level is different from at least one of the first layout level, the second layout level or the third layout level.

In some embodiments, the BMD level is above the BM0 level. In some embodiments, the BMD level is below the back-side 403b of integrated circuit 400. In some embodiments, the BMD level is below the OD level, the POLY level, the MD level and the M0 level.

Other configurations, arrangements on other layout levels or quantities of patterns in the set of contact patterns 312 are within the scope of the present disclosure.

Layout design 300 further includes one or more contact patterns 314a, 314b, 314c (collectively referred to as a “set of contact patterns 314”) extending in the second direction Y.

Each of the contact patterns of the set of contact patterns 314 is separated from an adjacent contact pattern of the set of contact patterns 314 in at least the first direction X or the second direction Y.

In some embodiments, the set of contact patterns 314 is between the set of contact patterns 310 and 312. Contact pattern 314a is between contact patterns 310a and 310b. Contact pattern 314a is between contact patterns 312a and 312b. Contact pattern 314b is between contact patterns 310c and 310d. Contact pattern 314b is between contact patterns 312c and 312d.

Contact pattern 314c is between contact patterns 312d and 312f.

Contact pattern 314c is between contact patterns 310d and 310f.

In some embodiments, contact pattern 314a includes one or more separate discontinuous patterns. In some embodiments, contact pattern 314b includes one or more separate discontinuous patterns. In some embodiments, contact pattern 314c includes one or more separate discontinuous patterns.

Contact patterns 314a and 314b are separated from one another in the first direction X.

Contact pattern 314c is separated from at least one of contact pattern 314a or 314b in the first direction X or the second direction Y.

The set of contact patterns 314 is usable to manufacture a corresponding set of contacts 414 of integrated circuit 100, 200A, 200B, 400 or 500.

In some embodiments, contact pattern 314a, 314b, 314c of the set of contact patterns 314 is usable to manufacture corresponding contact 414a, 414b, 414c of the set of contacts 414. In some embodiments, the set of contacts 414 are on a front-side 403a of integrated circuit 400. In some embodiments, the set of contacts patterns 314 is also referred to as a set of local interconnect (MDLI) patterns.

In some embodiments, at least one of contact pattern 314a, 314b, 314c of the set of contact patterns 314 is usable to manufacture interconnect structures usable to connect source or drain terminals of one of the NFET or PFET transistors of integrated circuit 100, 200A, 200B, 400 or 500.

In some embodiments, contact pattern 314a is usable to manufacture drain/source terminals of NFET transistor PD1, drain/source terminals of NFET WPG1, drain/source terminals of PFET transistor PU1 and drain/source terminals of PFET X1.

In some embodiments, contact pattern 314a corresponds to node NDB of FIGS. 2A-2B, and similar detailed description is omitted for brevity.

In some embodiments, contact pattern 314b is usable to manufacture drain/source terminals of NFET transistor WPG2, drain/source terminals of NFET transistor PD2, drain/source terminals of PFET transistor X2 and drain/source terminals of PFET transistor PU2.

In some embodiments, contact pattern 314b corresponds to node ND of FIGS. 2A-2B, and similar detailed description is omitted for brevity.

In some embodiments, contact pattern 314c is usable to manufacture drain/source terminals of NFET transistor RPD1 and drain/source terminals of PFET transistor RPD2.

In some embodiments, at least a first portion of the set of contact patterns 314 are overlapped by one or more of the set of active region patterns 302 or 304. In some embodiments, at least a second portion of the set of contact patterns 314 is between the set of active region patterns 302 or 304. In some embodiments, at least a third portion of the set of contact patterns 314 is coplanar with the set of contact patterns 310 or the set of contact patterns 312.

The set of contact patterns 314 is located on a fifth layout level. In some embodiments, the fifth layout level corresponds to the MDLI level of one or more of layout design 300 or integrated circuits 100, 200A, 200B, 400 or 500. In some embodiments, the fifth layout level is different from at least one of the first layout level or the second layout level.

In some embodiments, the MDLI level includes the MD level and the BMD level. In some embodiments, the MDLI level is below the M0 level. In some embodiments, the MDLI level is above the BM0 level.

Other configurations, arrangements on other layout levels or quantities of patterns in the set of contact patterns 314 are within the scope of the present disclosure.

Layout design 300 further includes one or more conductive feature patterns 316a and 316b (collectively referred to as a “set of conductive feature patterns 316”) extending in the first direction X and the second direction Y.

Each of the conductive feature patterns of the set of conductive feature patterns 316 is separated from an adjacent conductive feature pattern of the set of conductive feature patterns 316 in at least the first direction X or the second direction Y.

Conductive feature patterns 316a and 316b are separated from one another in at least the first direction X or the second direction Y.

The set of conductive feature patterns 316 is usable to manufacture a corresponding set of conductors 416 of integrated circuit 100, 200A, 200B, 400 or 500.

In some embodiments, conductive feature pattern 316a, 316b of the set of conductive feature patterns 316 is usable to manufacture corresponding conductor 416a, 416b of the set of conductors 416. The set of conductors 416 is on the back-side 403b of integrated circuit 400. Conductor 416a or 416b is on the back-side 403b of integrated circuit 400. In some embodiments, the set of conductive feature patterns 316 is also referred to as a set of VDR conductive feature patterns. In some embodiments, the set of conductors 416 is also referred to as a set of VDR conductors.

In some embodiments, at least one of conductive feature pattern 316a, 316b of the set of conductive feature patterns 316 is usable to manufacture interconnect structures usable to connect at least a gate terminal of one of the NFET or PFET transistors of integrated circuit 100, 200A, 200B, 400 or 500 to one or more source or drain terminals of another of the NFET or PFET transistors of integrated circuit 100, 200A, 200B, 400 or 500.

In some embodiments, the set of conductive feature patterns 316 is overlapped by one or more of the set of active region patterns 302, the set of active region patterns 304, the set of gate patterns 306, the set of gate patterns 308 or the set of contact patterns 314.

In some embodiments, conductive feature pattern 316a is overlapped by at least one of gate pattern 306b, gate pattern 308b or contact pattern 314a. In some embodiments, conductive feature pattern 316b is overlapped by at least one of gate pattern 306a, gate pattern 308a or contact pattern 314b.

The set of conductive feature patterns 316 is located on a sixth layout level. In some embodiments, the sixth layout level corresponds to the VDR level of one or more of layout design 300 or 600 or integrated circuits 100, 200A, 200B, 400 or 500. In some embodiments, the sixth layout level is different from at least one of the first layout level, the second layout level, the third layout level, the fourth layout level or the fifth layout level. In some embodiments, the VDR level is between the BM0 level and at least one of the OD level, the POLY level, the BMD level or the MDLI level.

Other configurations, arrangements on other layout levels or quantities of patterns in the set of conductive feature patterns 316 are within the scope of the present disclosure.

Layout design 300 further includes one or more conductive feature patterns 330a, 330b, 330c, 330d, 330e, 330f (collectively referred to as a “set of conductive feature patterns 330”) extending in the second direction Y.

Each conductive feature pattern in the set of conductive feature patterns 330 is separated from another conductive feature pattern in the set of conductive feature patterns 330 in the first direction X.

The set of conductive feature patterns 330 overlap at least one of the set of active region patterns 302 or 304, the set of gate patterns 306 or 308, the set of contact patterns 310, 312 or 314 or the set of conductive feature patterns 316.

The set of conductive feature patterns 330 is usable to manufacture a corresponding set of conductors 430 of integrated circuit 100, 200A, 200B, 400 or 500. Conductive feature patterns 330a, 330b, 330c, 330d, 330e, 330f are usable to manufacture corresponding conductors 430a, 430b, 430c, 430d, 430e, 430f of integrated circuit 100, 200A, 200B, 400 or 500. In some embodiments, at least one conductor of the set of conductors 430 is located on the front-side 403a of integrated circuit 100, 200A, 200B, 400 or 500.

In some embodiments, the set of conductive feature patterns 330 is located on a seventh layout level. In some embodiments, the seventh layout level is different from at least one of the first layout level, the second layout level, the third layout level, the fourth layout level, the fifth layout level or the sixth layout level. In some embodiments, the seventh layout level corresponds to the M0 level of one or more of layout design 300 or integrated circuits 100, 200A, 200B, 400 or 500. In some embodiments, the M0 level is above the OD level, the POLY level, the MD level, the BMD level, the MDLI level, the VDR level and the BM0 level.

In some embodiments, the set of conductive feature patterns 330 correspond to 6 M0 routing tracks. Other numbers of M0 routing tracks are within the scope of the present disclosure.

Other configurations, arrangements on other layout levels or quantities of patterns in the set of conductive feature patterns 330 are within the scope of the present disclosure.

Layout design 300 further includes one or more conductive feature patterns 332a, 332b, 332c, 332d, 332e (collectively referred to as a “set of conductive feature patterns 332”) extending in the first direction X.

Each conductive feature pattern in the set of conductive feature patterns 332 is separated from another conductive feature pattern in the set of conductive feature patterns 332 in the second direction Y.

The set of conductive feature patterns 332 is overlapped by at least one of the set of active region patterns 302 or 304, the set of gate patterns 306 or 308, the set of contact patterns 310, 312 or 314 or the set of conductive feature patterns 316.

The set of conductive feature patterns 330 and 332 are separated from one another in the third direction Z. In some embodiments, conductive feature pattern 330a is separated from at least one of conductive feature pattern 332a or 332b in the third direction Z. In some embodiments, conductive feature patterns 330c and 332c are separated from one another in the third direction Z. In some embodiments, conductive feature patterns 330d and 332d are separated from one another in the third direction Z. In some embodiments, conductive feature patterns 330f and 332e are separated from one another in the third direction Z.

The set of conductive feature patterns 332 is usable to manufacture a corresponding set of conductors 432 of integrated circuit 100, 200A, 200B, 400 or 500. Conductive feature patterns 332a, 332b, 332c, 332d, 332e are usable to manufacture corresponding conductors 432a, 432b, 432c, 432d, 432e of integrated circuit 100, 200A, 200B, 400 or 500. In some embodiments, at least one conductor of the set of conductors 432 is located on the back-side 403b of integrated circuit 100, 200A, 200B, 400 or 500.

In some embodiments, the set of conductive feature patterns 332 is located on an eighth layout level. In some embodiments, the eighth layout level is different from at least one of the first layout level, the second layout level, the third layout level, the fourth layout level, the fifth layout level, the sixth layout level or the seventh layout level. In some embodiments, the eighth layout level corresponds to the BM0 level of one or more of layout design 300 or integrated circuits 100, 200A, 200B, 400 or 500. In some embodiments, the BM0 level is below the OD level, the POLY level, the MD level, the BMD level, the MDLI level, the VDR level and the BM0 level.

In some embodiments, the set of conductive feature patterns 332 correspond to 4 BM0 routing tracks. Other numbers of BM0 routing tracks are within the scope of the present disclosure.

Other configurations, arrangements on other layout levels or quantities of patterns in the set of conductive feature patterns 332 are within the scope of the present disclosure.

Layout design 300 further includes one or more via patterns 320a, 320b, 320c, 320d, 320e, 320f (collectively referred to as a “set of via patterns 320”).

The set of via patterns 320 is usable to manufacture a corresponding set of vias 420 of integrated circuit 100, 200A, 200B, 400 or 500. In some embodiments, via patterns 320a, 320b, 320c, 320d, 320e, 320f of the set of via patterns 320 are usable to manufacture corresponding vias 420a, 420b, 420c, 420d, 420e, 420f of the set of vias 420 of integrated circuit 100, 200A, 200B, 400 or 500.

In some embodiments, the set of via patterns 320 is between the set of contact patterns 310 and the set of conductive feature patterns 330.

Via pattern 320a is between contact pattern 310a and conductive feature pattern 330a.

Via pattern 320b is between contact pattern 310b and conductive feature pattern 330b.

Via pattern 320c is between contact pattern 310c and conductive feature pattern 330c.

Via pattern 320d is between contact pattern 310d and conductive feature pattern 330d.

Via pattern 320e is between contact pattern 310e and conductive feature pattern 330d.

Via pattern 320f is between contact pattern 314c and conductive feature pattern 330e.

The set of via patterns 320 is positioned at a via over diffusion (VD) level of one or more of layout design 300 or integrated circuits 100, 200A, 200B, 400 or 500. In some embodiments, the VD level is above the OD level, the POLY level, the MD level, the BMD level, the MDLI level, the VDR level and the BM0 level. In some embodiments, the VD level is below the M0 level. In some embodiments, the VD level is between the MD level and the M0 level. In some embodiments, the VD level is between the third layout level and the seventh layout level. Other layout levels are within the scope of the present disclosure.

Other configurations, arrangements on other layout levels or quantities of patterns in at least set of via patterns 320 are within the scope of the present disclosure.

Layout design 300 further includes one or more via patterns 322a, 322b, 322c (collectively referred to as a “set of via patterns 322”).

The set of via patterns 322 is usable to manufacture a corresponding set of vias 422 of integrated circuit 100, 200A, 200B, 400 or 500. In some embodiments, via patterns 322a, 322b, 322c of the set of via patterns 322 are usable to manufacture corresponding vias 422a, 422b, 422c of the set of vias 422 of integrated circuit 100, 200A, 200B, 400 or 500.

In some embodiments, the set of via patterns 322 is between the set of contact patterns 312 and the set of conductive feature patterns 332.

Via pattern 322a is between contact pattern 312a and conductive feature pattern 332b.

Via pattern 322b is between contact pattern 312d and conductive feature pattern 332d.

Via pattern 322c is between contact pattern 312e and conductive feature pattern 332d.

The set of via patterns 322 is positioned at a back-side via over diffusion (BVD) level of one or more of layout design 300 or integrated circuits 100, 200A, 200B, 400 or 500. In some embodiments, the BVD level is below the OD level, the POLY level, the MD level, the BMD level and the M0 level. In some embodiments, the BVD level is above the BM0 level. In some embodiments, the BVD level is between the BMD level and the BM0 level. In some embodiments, the BVD level is between the fourth layout level and the eighth layout level. Other layout levels are within the scope of the present disclosure.

Other configurations, arrangements on other layout levels or quantities of patterns in at least set of via patterns 322 are within the scope of the present disclosure.

Layout design 300 further includes one or more via patterns 324a (collectively referred to as a “set of via patterns 324”).

The set of via patterns 324 is usable to manufacture a corresponding set of vias 424 of integrated circuit 100, 200A, 200B, 400 or 500. In some embodiments, via patterns 324a of the set of via patterns 324 are usable to manufacture corresponding vias 424a of the set of vias 424 of integrated circuit 100, 200A, 200B, 400 or 500.

In some embodiments, the set of via patterns 324 is between the set of gate patterns 306 and the set of conductive feature patterns 330. Via pattern 324a is between gate pattern 306a and conductive feature pattern 330f.

The set of via patterns 324 is positioned at a via over gate (VG) level of one or more of layout design 300 or integrated circuits 100, 200A, 200B, 400 or 500. In some embodiments, the VG level is above the OD level, the POLY level, the MD level, the MDLI level, the VDR level, the BMD level and the BM0 level. In some embodiments, the VG level is below the M0 level. In some embodiments, the VG level is between the POLY level and the M0 level. In some embodiments, the VG level is between the second layout level and the seventh layout level. Other layout levels are within the scope of the present disclosure.

Other configurations, arrangements on other layout levels or quantities of patterns in at least set of via patterns 324 are within the scope of the present disclosure.

Layout design 300 further includes one or more via patterns 326a, 326b, 326c (collectively referred to as a “set of via patterns 326”).

The set of via patterns 326 is usable to manufacture a corresponding set of vias 426 of integrated circuit 100, 200A, 200B, 400 or 500. In some embodiments, via patterns 326a, 326b, 326c of the set of via patterns 326 are usable to manufacture corresponding vias 426a, 426b, 426c of the set of vias 426 of integrated circuit 100, 200A, 200B, 400 or 500.

In some embodiments, the set of via patterns 326 is between the set of gate patterns 308 and the set of conductive feature patterns 332.

Via pattern 326a is between gate pattern 308b and conductive feature pattern 332a.

Via pattern 326b is between gate pattern 308a and conductive feature pattern 332c.

Via pattern 326c is between gate pattern 308a and conductive feature pattern 332e.

The set of via patterns 326 is positioned at a back-side via over gate (BVG) level of one or more of layout design 300 or integrated circuits 100, 200A, 200B, 400 or 500. In some embodiments, the BVG level is below the OD level, the POLY level, the MD level, the MDLI level, the VDR level, the BMD level and the M0 level. In some embodiments, the BVG level is above the BM0 level. In some embodiments, the BVG level is between the POLY level and the BM0 level. In some embodiments, the BVG level is between the second layout level and the eighth layout level. Other layout levels are within the scope of the present disclosure.

Other configurations, arrangements on other layout levels or quantities of patterns in at least set of via patterns 326 are within the scope of the present disclosure.

In some embodiments, by including the set of insulating region patterns 394 in layout design 300, gate pattern 306a and 308a are separated from each other by insulating region pattern 394a, thereby allowing NFET transistor RPG1 and PFET transistor RPG2 to be used as separate transistors configured to operate independent of each other in a CMOS configuration of at least one read port of a multi-port memory cell manufactured by layout design 300, thereby resulting in a layout design of a multi-port memory cell that occupies less area than other approaches.

In some embodiments, by configuring NFET transistor RPG1 and PFET transistor RPG2 to be used as separate transistors and configured to operate independent of each other in a CMOS configuration of at least one read port of a multi-port memory cell manufactured by layout design 300, thereby resulting in a layout design of a multi-port memory cell that has improved speed compared to other approaches.

Other configurations, arrangements on other layout levels or quantities of patterns in layout design 300 are within the scope of the present disclosure.

FIGS. 4A-4L are diagrams of an integrated circuit 400, in accordance with some embodiments.

FIGS. 4A-4F are corresponding diagrams of corresponding portions 400A-400F of an integrated circuit 400, simplified for ease of illustration.

Portion 400A includes one or more features of integrated circuit 400 of the OD level, the POLY level, the CPO level, the MD level, the MDLI level, the VG level and the VD level. Portion 400A is manufactured by portion 300A.

Portion 400B includes one or more features of integrated circuit 400 of the OD level, the POLY level, the CPO level, the BMD level, the MDLI level, the VDR level, the BVG level and the BVD level. Portion 400B is manufactured by portion 300B.

Portion 400C includes one or more features of integrated circuit 400 of the M0 level. Portion 400C is manufactured by portion 300C.

Portion 400D includes one or more features of integrated circuit 400 of the BM0 level. Portion 400D is manufactured by portion 300D.

Portion 400E includes one or more features of integrated circuit 400 of the OD level, the POLY level, the CPO level, the MD level, the MDLI level, the VG level, the VD level and the M0 level. Portion 400E is manufactured by portion 300E.

Portion 400F includes one or more features of integrated circuit 400 of the OD level, the POLY level, the CPO level, the BMD level, the MDLI level, the VDR level, the BVG level, the BVD level and the BM0 level. Portion 400F is manufactured by portion 300F.

FIGS. 4G-4L are corresponding cross-sectional views of integrated circuit 400, in accordance with some embodiments. FIG. 4G is a cross-sectional view of integrated circuit 400 as intersected by plane A-A′, in accordance with some embodiments. FIG. 4H is a cross-sectional view of integrated circuit 400 as intersected by plane B-B′, in accordance with some embodiments. FIG. 4I is a cross-sectional view of integrated circuit 400 as intersected by plane C-C′, in accordance with some embodiments. FIG. 4J is a cross-sectional view of integrated circuit 400 as intersected by plane D-D′, in accordance with some embodiments. FIG. 4K is a cross-sectional view of integrated circuit 400 as intersected by plane E-E′, in accordance with some embodiments. FIG. 4L is a cross-sectional view of integrated circuit 400 as intersected by plane F-F′, in accordance with some embodiments.

Components that are the same or similar to those in one or more of FIGS. 1, 2A-2B, 3A-3F, 4A-4L, 5A-5E and 6A-6B are given the same reference numbers, and detailed description thereof is thus omitted.

Integrated circuit 400 is manufactured by layout design 300. Integrated circuit 400 is cell 401. Structural relationships including alignment, lengths and widths, as well as configurations and layers of integrated circuit 400 and 600 are similar to the structural relationships and configurations and layers of layout design 300 of FIGS. 3A-3F, and similar detailed description will not be described in at least FIGS. 4A-4L, for brevity. For example, in some embodiments, at least one or more widths, lengths or pitches of layout design 300 is similar to corresponding widths, lengths or pitches of integrated circuit 400 and 500, and similar detailed description is omitted for brevity. For example, in some embodiments, at least cell boundary 301a or 301b is similar to at least corresponding cell boundary 401a or 401b of integrated circuit 400, and similar detailed description is omitted for brevity.

Integrated circuit 400 includes at least the set of active regions 402 and 404, the set of gates 406 and 408, the set of removed gate portions 440, the set of contacts 410, the set of contacts 412, the set of contacts 414, the set of conductors 416, the set of conductors 430, the set of conductors 432, the set of vias 420, the set of vias 422, the set of vias 424, the set of vias 426, a substrate 490, an insulating region 492 and a set of insulating regions 494.

The set of active regions 402 includes at least one or more active regions 402a, 402b, 402c.

The set of active regions 404 includes at least one or more active regions 404a, 404b, 404c.

The set of active regions 402 and 404 are embedded in a substrate 490. Substrate 490 has a front-side 403a and a back-side 403b opposite from the front-side 403a. In some embodiments, at least the set of active regions 402 and 404, the set of gates 406 and 408 or the set of contacts 410, 412 or 414 are formed in the front-side 403a of substrate 490.

In some embodiments, at least the set of conductors 416, the set of vias 422 or the set of vias 426 are formed in the front-side 403a of substrate 490.

In some embodiments, the set of active regions 402 and 404 correspond to active regions of CFET transistors. In some embodiments, the set of active regions 402 include drain regions and source regions grown by an epitaxial growth process. In some embodiments, the set of active regions 402 include drain regions and source regions that are grown with an epitaxial material at the corresponding drain regions and source regions. In some embodiments, the set of active regions 402 and 404 correspond to nanosheet structures (not labelled) of nanosheet transistors.

Other transistor types are within the scope of the present disclosure. For example, in some embodiments, the set of active regions 402 corresponds to nanowire structures (not shown) of nanowire transistors. In some embodiments, the set of active regions 402 corresponds to planar structures (not shown) of planar transistors. In some embodiments, the set of active regions 402 corresponds to fin structures (not shown) of finFETs.

In some embodiments, active regions 402a, 402b and 402c correspond to source and drain regions of NFET transistors of integrated circuit 100, 200A, 200B, 400 or 500, and active regions 404a, 404b and 404c correspond to source and drain regions of PFET transistors of integrated circuit 100, 200A, 200B, 400 or 500.

In some embodiments, active regions 402a, 402b and 402c correspond to source and drain regions of PFET transistors of integrated circuit 100, 200A, 200B, 400 or 500, and active regions 404a, 404b and 404c correspond to source and drain regions of NFET transistors of integrated circuit 100, 200A, 200B, 400 or 500.

In some embodiments, at least active region 402a, 402b or 402c is an N-type doped S/D region, and at least active region 404a, 404b or 404c is a P-type doped S/D region embedded in a dielectric material of substrate 490. In some embodiments, at least active region 402a, 402b or 402c is a P-type doped S/D region, and at least active region 404a, 404b or 404c is an N-type doped S/D region embedded in a dielectric material of substrate 490.

In some embodiments, active region 404a includes at least one of active regions 404a1, 404a2 or 404a3.

In some embodiments, active region 404a3 is the source/drain of PFET transistor PU1.

In some embodiments, active region 404a2 is the drain/source of PFET transistor PU1.

In some embodiments, active region 404a1 is the drain/source of PFET transistor X1. In some embodiments, active region 404a1 includes an insulating region 480a. In some embodiments, active region 404a1 is a dummy active region that has been removed and is filled with insulating region 480a.

In some embodiments, active region 404b includes at least one of active regions 404b1, 404b2 or 404b3.

In some embodiments, active region 404b3 is the source/drain of PFET transistor PU2.

In some embodiments, active region 404b2 is the drain/source of PFET transistor PU2.

In some embodiments, active region 404b1 is the drain/source of PFET transistor X2. In some embodiments, active region 404b1 includes an insulating region 480b. In some embodiments, active region 404b1 is a dummy active region that has been removed and is filled with insulating region 480b.

In some embodiments, at least one of insulating region 480a or 480b is a dielectric material. In some embodiments, the dielectric material includes silicon dioxide, silicon oxy-nitride, silicon nitride or the like.

Other configurations, arrangements on other layout levels or quantities of structures in the set of active regions 402 or 404 are within the scope of the present disclosure.

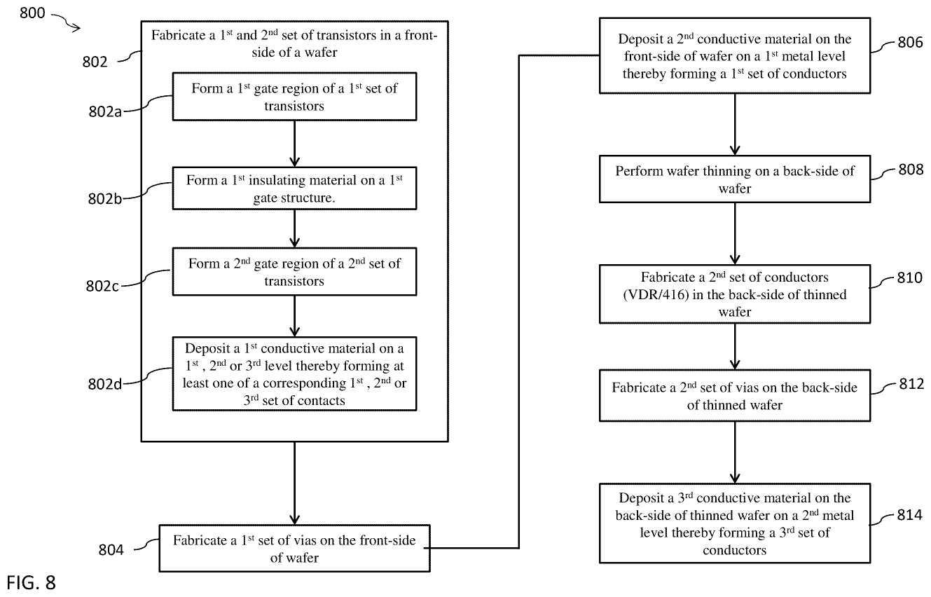

Insulating region 492 is configured to electrically isolate one or more elements of the the set of active regions 402 and 404, the set of gates 406 and 408, the set of contacts 410, the set of contacts 412, the set of contacts 414, the set of conductors 416, the set of conductors 430, the set of conductors 432, the set of vias 420, the set of vias 422, the set of vias 424 or the set of vias 426 from one another. In some embodiments, insulating region 492 includes multiple insulating regions deposited at different times from each other during method 800 (FIG. 8). In some embodiments, insulating region 492 is a dielectric material. In some embodiments, the dielectric material includes silicon dioxide, silicon oxy-nitride, silicon nitride, or the like.

Other configurations, arrangements on other layout levels or other numbers of portions in insulating region 492 are within the scope of the present disclosure.

The set of gates 406 include one or more gates 406a or 406b.

The set of gates 408 include one or more gates 408a or 408b.

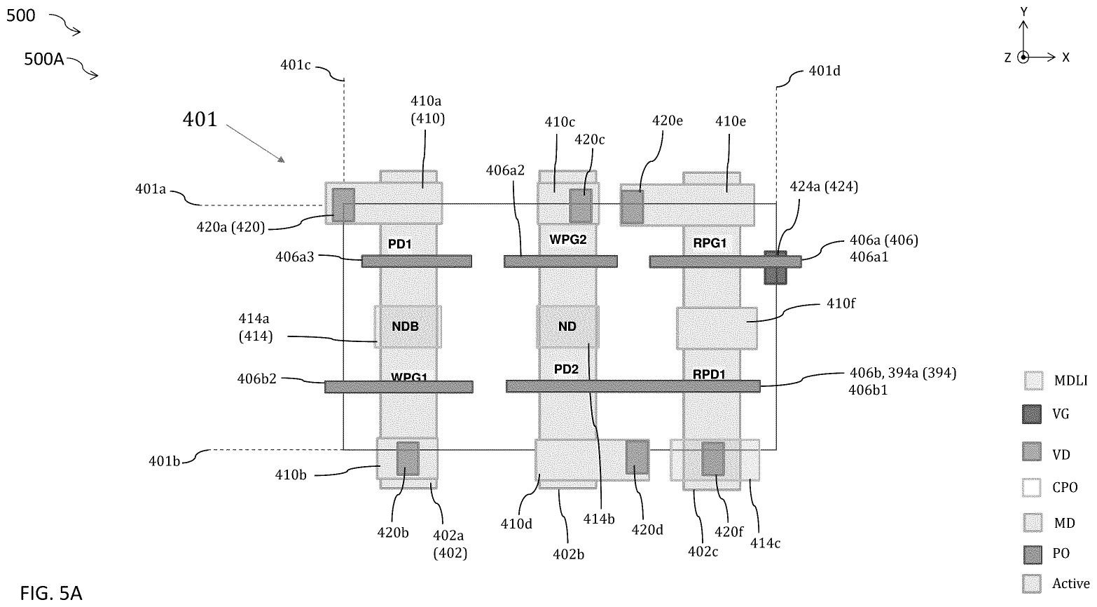

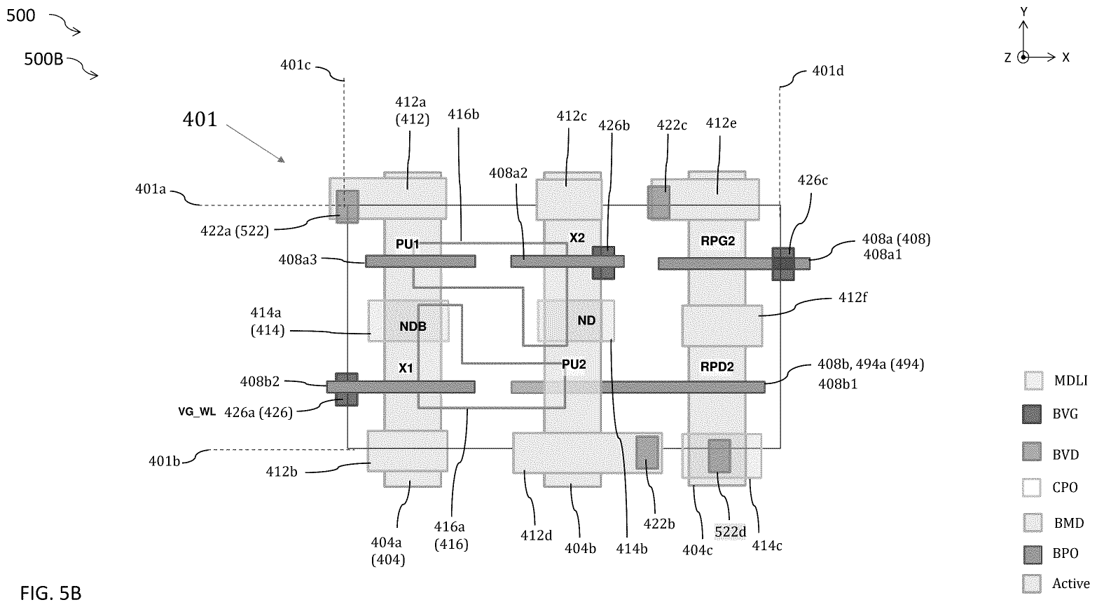

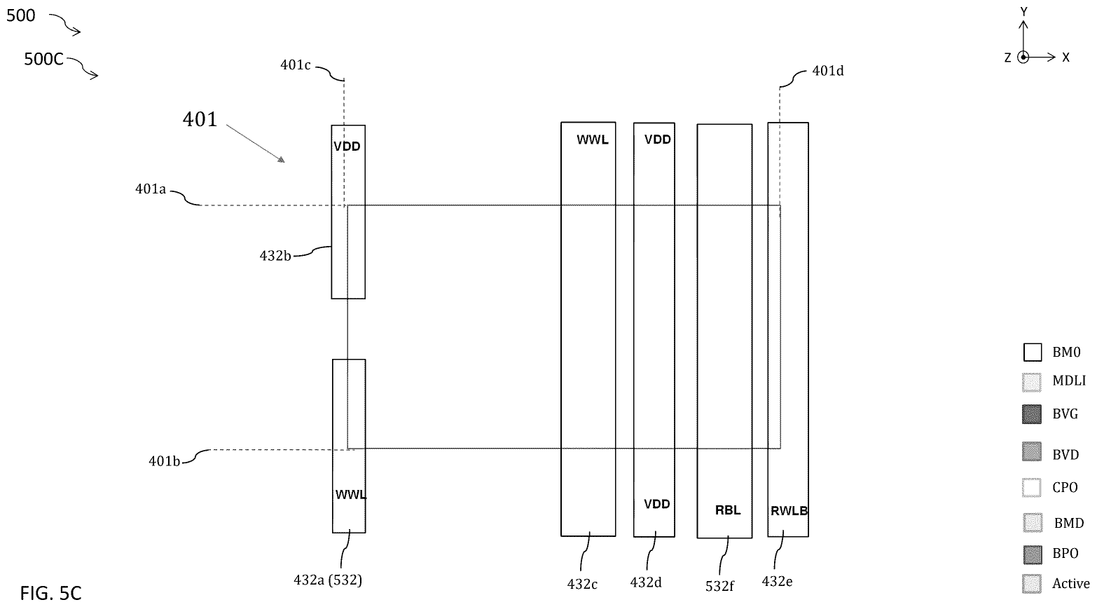

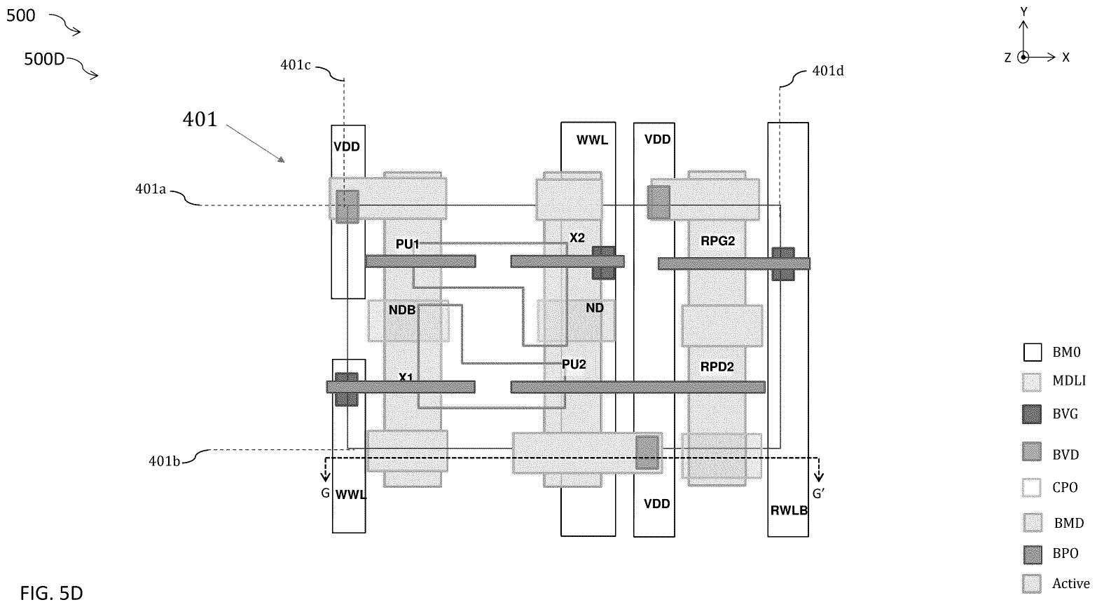

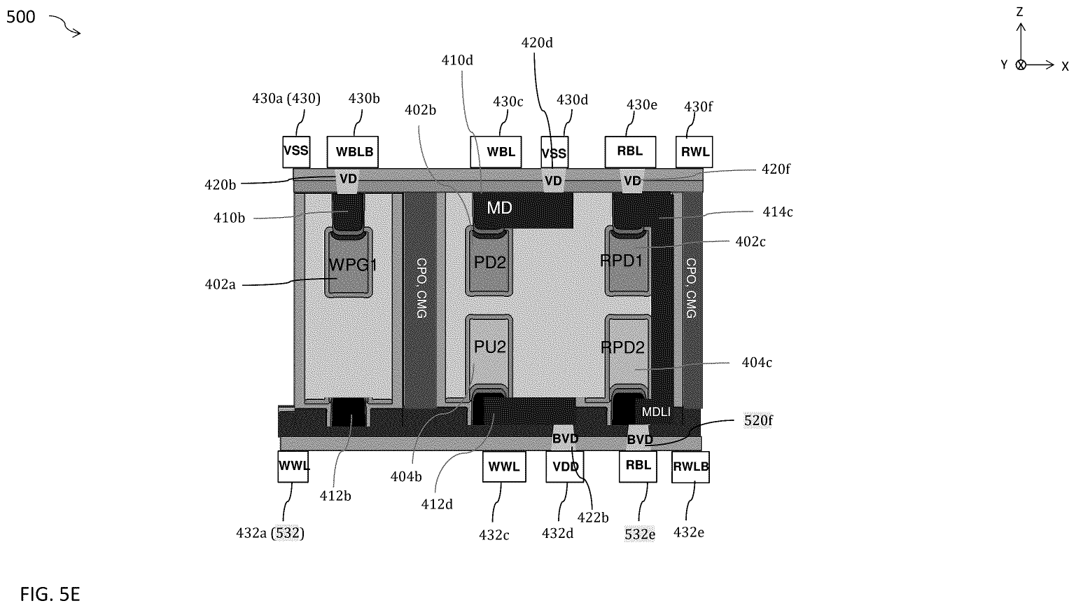

The set of gates 406 and 408 correspond to one or more gates of transistors PD1, PU1, PD2, PU2, WPG1, WPG2, RPD1, RPD2, RPG1, RPG2, X1, X2 of integrated circuits 100, 200A, 200B, 400 or 500. In some embodiments, each of the gates in the set of gates 406 and 408 are shown in FIGS. 4A-4F with labels “PD1, PU1, PD2, PU2, WPG1, WPG2, RPD1, RPD2, RPG1, RPG2, X1, X2” that identify corresponding transistors of FIGS. 2A-2B having corresponding gates in FIGS. 4A-4L and 5, and are omitted for brevity.

Gate 406a includes one or more gates 406a1, 406a2 or 406a3.

Gate 406b includes one or more gates 406b1 or 406b2.

Gate 408a includes one or more gates 408a1, 408a2 or 408a3.

Gate 408b includes one or more gates 408b1 or 408b2.

In some embodiments, gate 406a1 is a gate of NFET transistor RPG1, gate 406a2 is a gate of NFET transistor WPG2, gate 406a3 is a gate of NFET transistor PD1, gate 406b1 is a gate of NFET transistor RPD1 and a gate of NFET transistor PD2, and gate 406b2 is a gate of NFET transistor WPG1.

In some embodiments, gate 408a1 is a gate of PFET transistor RPG2, gate 408a2 is a gate of PFET transistor X2, gate 408a3 is a gate of PFET transistor PU1, gate 408b1 is a gate of PFET transistor RPD2 and a gate of PFET transistor PU2, and gate 408b2 is a gate of PFET transistor X1.

In some embodiments, gate 406a1 and gate 406a2 are separated from each other in the first direction X by removed gate portion 440c.

In some embodiments, gate 406a2 and gate 406a3 are separated from each other in the first direction X by removed gate portion 440b.

In some embodiments, gate 406b1 and gate 406b2 are separated from each other in the first direction X by removed gate portion 440b.

In some embodiments, gate 408a1 and gate 408a2 are separated from each other in the first direction X by removed gate portion 440c.

In some embodiments, gate 408a2 and gate 408a3 are separated from each other in the first direction X by removed gate portion 440b.

In some embodiments, gate 408b1 and gate 408b2 are separated from each other in the first direction X by removed gate portion 440b.

In some embodiments, at least one of gate 406a1, 406a2, or 406a3 are of the same continuous structure. In some embodiments, at least one of gate 408a1, 408a2, or 408a3 are of the same continuous structure. In some embodiments, at least one of gate 406b1 or 406b2 are of the same continuous structure. In some embodiments, at least one of gate 408b1 or 408b2 are of the same continuous structure.

In some embodiments, gate 406a1 and gate 408a1 are separated from each other in the third direction Z. In some embodiments, gate 406a1 and gate 408a1 are separated from each other in the third direction Z by an insulating region 494a of the set of insulating regions 494.

In some embodiments, gate 406a2 and gate 408a2 are coupled together. In some embodiments, gate 406a2 and gate 408a2 are part of the same continuous structure.

In some embodiments, gate 406a3 and gate 408a3 are coupled together. In some embodiments, gate 406a3 and gate 408a3 are part of the same continuous structure.

In some embodiments, gate 406b1 and gate 408b1 are coupled together. In some embodiments, gate 406b1 and gate 408b1 are part of the same continuous structure.

In some embodiments, gate 406b2 and gate 408b2 are coupled together. In some embodiments, gate 406b2 and gate 408b2 are part of the same continuous structure.

In some embodiments, the set of gates 406 or 408 encapsulates the set of active regions 402 or 404.

Other configurations, arrangements on other layout levels or quantities of gates in the set of gates 406 and 408 are within the scope of the present disclosure.

The set of removed gate portions 440 include one or more removed gate portion 440a, 440b, 440c or 440d.

In some embodiments, one or more removed gate portions 440a, 440b, 440c or 440d includes a corresponding insulating region (not labelled) similar to the set of insulating regions 494, and similar detailed description is therefore omitted.

In some embodiments, the removed gate portion 440a separates gate 406a3 and gate 408a3 from a gate in an adjacent cell along cell boundary 401c.

In some embodiments, the removed gate portion 440d separates gate 406b1 and gate 408b1 from a gate in an adjacent cell along cell boundary 401d.

In some embodiments, the one or more removed gate portions 440a, 440b, 440c or 440d is configured to electrically isolate the gates that are adjacent to the corresponding the one or more removed gate portions 440a, 440b, 440c or 440d.

Other configurations, arrangements on other layout levels or quantities of removed gate portions in the set of removed gate portions 440 are within the scope of the present disclosure.

The set of insulating regions 494 includes at least one of insulating region 494a. In some embodiments, the set of insulating regions 494 are also referred to as a set of gate isolation layers. In some embodiments, at least one of insulating region 494a is referred to as a gate isolation layer.

The set of insulating regions 494 is configured to electrically isolate one or more gates of the set of gates 406 or 408 from another gate of the set of gates 406 or 408.

In some embodiments, insulating region 494a is configured to electrically isolate gate 406a1 and gate 408a1 from each other.

In some embodiments, set of insulating regions 494a includes a single insulating region deposited at a single instant of time during method 800 (FIG. 8). In some embodiments, insulating region 494a includes multiple insulating regions deposited at different times from each other during method 800 (FIG. 8). In some embodiments, insulating region 494 is a dielectric material. In some embodiments, the dielectric material includes silicon dioxide, silicon oxy-nitride, silicon nitride or the like.

Other configurations, arrangements on other layout levels or other numbers of portions in the set of insulating regions 494 are within the scope of the present disclosure.

The set of contacts 410 includes one or more contacts 410a, 410b, 410c, 410d, 410e or 410f.

The set of contacts 412 includes one or more contacts 412a, 412b, 412c, 412d, 412e or 412f.

Each contact of the set of contacts 410 or 412 corresponds to one or more drain or source terminals of transistors PD1, PU1, PD2, PU2, WPG1, WPG2, RPD1, RPD2, RPG1, RPG2, X1, X2 of integrated circuits 100, 200A, 200B, 400 or 500.

In some embodiments, one or more contacts of the set of contacts 410 overlaps a pair of active regions of the set of active regions 402, thereby electrically coupling the pair of active regions of the set of active regions 402, and the source or drain of the corresponding transistors.

In some embodiments, one or more contacts of the set of contacts 412 is overlapped by a pair of active regions of the set of active regions 404, thereby electrically coupling the pair of active regions of the set of active regions 404, and the source or drain of the corresponding transistors.

In some embodiments, the set of contacts 410 or 412 encapsulates the set of active regions 402 or 404.

In some embodiments, contact 410a is a source/drain terminal of NFET transistor PD1.

In some embodiments, contact 410b is a source/drain terminal of NFET transistor WPG1.

In some embodiments, contact 410c is a source/drain terminal of NFET transistor WPG2.

In some embodiments, contact 410d is a source/drain terminal of NFET transistor PD2.

In some embodiments, contact 410e is a source/drain terminal of NFET transistor RPG1.

In some embodiments, contact 410f is a drain/source terminal of NFET transistor RPG1, and source/drain terminal of NFET transistor RPD1.

In some embodiments, contact 412a is a source/drain terminal of PFET transistor PU1.

In some embodiments, contact 412b is a source/drain terminal of PFET transistor X1.

In some embodiments, contact 412c is a source/drain terminal of PFET transistor X2.

In some embodiments, contact 412d is a source/drain terminal of PFET transistor PU2.

In some embodiments, contact 412e is a source/drain terminal of PFET transistor RPG2.

In some embodiments, contact 412f is a drain/source terminal of PFET transistor RPG2, and a source/drain terminal of PFET transistor RPD2.

The set of contacts 414 includes one or more contacts 414a, 414b or 414c.

In some embodiments, contact 414a is a drain/source terminal of NFET transistor PD1, a drain/source terminal of NFET WPG1, a drain/source terminal of PFET transistor PU1 and a drain/source terminal of PFET X1.

In some embodiments, contact 414a corresponds to node NDB of FIGS. 2A-2B, and similar detailed description is omitted for brevity.

In some embodiments, contact 414b is a drain/source terminal of NFET transistor WPG2, a drain/source terminal of NFET transistor PD2, a drain/source terminal of PFET transistor X2 and a drain/source terminal of PFET transistor PU2.

In some embodiments, contact 414b corresponds to node ND of FIGS. 2A-2B, and similar detailed description is omitted for brevity.

In some embodiments, contact 414c is a drain/source terminal of NFET transistor RPD1 and a drain/source terminal of PFET transistor RPD2.

Other configurations, arrangements on other layout levels or quantities of contacts in the set of contacts 410, 412 and 414 are within the scope of the present disclosure.

The set of conductors 416 includes one or more conductors 416a or 416b.

In some embodiments, conductor 416a is in direct contact with at least one of gate 408b1 or contact 414a.

In some embodiments, conductor 416a couples gate 408b1 with contact 414a, thereby electrically coupling the gate terminals of transistors PU2 and RPD2 with the drain terminals of transistors PD1 and PU1 and transistors WPG1 together.

In some embodiments, conductor 416b is in direct contact with at least one of gate 408a3 or contact 414b. In some embodiments, conductor 416b couples gate 408a3 with contact 414b, thereby electrically coupling the gate terminals of transistors PD1 and PU1 with the drain terminals of transistors WPG2 and transistors PD2 and PU2 together.

In some embodiments, each of conductors 416a or 416b includes a corresponding via (on a same level as the set of contacts 412) and a corresponding conductor that is embedded in the substrate 490.

Other configurations, arrangements on other layout levels or quantities of conductors in the set of conductors 416 are within the scope of the present disclosure.

The set of conductors 430 includes one or more conductors 430a, 430b, 430c, 430d, 430e or 430f.

The set of conductors 432 includes one or more conductors 432a, 432b, 432c, 432d or 432e.

The set of conductors 430 is M0 routing tracks. The set of conductors 432 is BM0 routing tracks. In some embodiments, the set of conductors 430 and 432 are routing tracks in other layers. In some embodiments, the set of conductors 430 corresponds to 6 M0 routing tracks. In some embodiments, the set of conductors 432 corresponds to 4 BM0 routing tracks.

In some embodiments, conductor 430a is configured to supply the reference supply voltage VSS, conductor 430b is the write bit line bar WBLB, conductor 430c is the write bit line WBL, conductor 430d is configured to supply the reference supply voltage VSS, conductor 430e is the read bit line RBL, and conductor 430f is the read bit line RWL.

In some embodiments, conductor 432a is the write word line WWL, conductor 432b is configured to supply the supply voltage VDD, conductor 432c is the write word line WWL, conductor 432d is configured to supply the supply voltage VDD, and conductor 432e is the read word line bar RWLB.

Other configurations, arrangements on other layout levels or quantities of conductors in the set of conductors 430 and 432 are within the scope of the present disclosure.

The set of vias 420 includes one or more vias 420a, 420b, 420c, 420d, 420e or 420f.

The set of vias 422 includes one or more vias 422a, 422b or 422c.

The set of vias 424 includes one or more vias 424a.

The set of vias 426 includes one or more vias 426a, 426b or 426c.

The set of vias 420 is configured to electrically couple a corresponding source or drain region of the set of active regions 402 to the set of conductors 430 by the set of contacts 410 or 414, and vice versa. The set of vias 420 is between the set of contacts 410 or 414 and the set of conductors 430.

The set of vias 422 is configured to electrically couple a corresponding source or drain region of the set of active regions 404 to the set of conductors 432 by the set of contacts 412 or 414, and vice versa. The set of vias 422 is between the set of contacts 412 or 414 and the set of conductors 432.

The set of vias 424 is configured to electrically couple one or more gates of the set of gates 406 to the set of conductors 430, and vice versa. The set of vias 424 is between the set of gates 406 and the set of conductors 430.

The set of vias 426 is configured to electrically couple one or more gates of the set of gates 408 to the set of conductors 432, and vice versa. The set of vias 426 is between the set of gates 408 and the set of conductors 432.

Via 420a electrically couples conductor 430a and contact 410a together. Via 420b electrically couples conductor 430b and contact 410b together. Via 420c electrically couples conductor 430c and contact 410c together. Via 420d electrically couples conductor 430d and contact 410d together. Via 420e electrically couples conductor 430d and contact 410e together. Via 420f electrically couples conductor 430e and contact 414c together.

Via 422a electrically couples conductor 432b and contact 412a together. Via 422b electrically couples conductor 432d and contact 412d together. Via 422c electrically couples conductor 432d and contact 412e together.

Via 424a electrically couples conductor 430f and gate 406a1 together.

Via 426a electrically couples conductor 432a and gate 408b2 together. Via 426b electrically couples conductor 432c and gate 408a2 together. Via 426c electrically couples conductor 432e and gate 408a1 together.

Other configurations, arrangements on other layout levels or quantities of vias in the set of vias 420, 422, 424 and 426 are within the scope of the present disclosure.

In some embodiments, at least one gate of the set of gates 406 or 408 are formed using a doped or non-doped polycrystalline silicon (or polysilicon). In some embodiments, at least one gate of the set of gates 406 or 408 include a metal, such as Al, Cu, W, Ti, Ta, TiN, TaN, NiSi, CoSi, other suitable conductive materials, or combinations thereof.

In some embodiments, at least one contact of the set of contacts 410, 412 or 414, or at least one conductor of the set of conductors 416, 430 or 432, or at least one via of the set of vias 420, 422, 424 or 426 includes one or more layers of a conductive material, a metal, a metal compound or a doped semiconductor. In some embodiments, the conductive material includes Tungsten, Cobalt, Ruthenium, Copper, or the like or combinations thereof. In some embodiments, a metal includes at least Cu (Copper), Co, W, Ru, Al, or the like. In some embodiments, a metal compound includes at least AlCu, W-TiN, TiSix, NiSix, TiN, TaN, or the like. In some embodiments, a doped semiconductor includes at least doped silicon, or the like.

In some embodiments, the gate isolation layer 494a electrically insulates gate 406a1 and gate 408a1 from each other. In some embodiments, by electrically insulating gate 406a1 and gate 408a1 from each other, memory cell 400 can be used as a multi-port memory cell with at least a first port and a second port that occupies less area than other approaches.

In some embodiments, by including the set of insulating regions 494 in integrated circuit 400, gate 406a1 and 408a1 are separated from each other by insulating region 494a, thereby allowing NFET transistor RPG1 and PFET transistor RPG2 to be used as separate transistors that are configured to operate independent of each other in a CMOS configuration of at least one read port of a multi-port memory cell, thereby resulting in an integrated circuit 400 that occupies less area than other approaches.

In some embodiments, by configuring NFET transistor RPG1 and PFET transistor RPG2 to be used as separate transistors and configured to operate independent of each other in a CMOS configuration of at least one read port of a multi-port memory cell, thereby resulting in integrated circuit 400 having improved speed compared to other approaches.

Other configurations or arrangements of integrated circuit 400 are within the scope of the present disclosure.

FIGS. 5A-5E are diagrams of an integrated circuit 500, in accordance with some embodiments.

FIGS. 5A-5D are corresponding diagrams of corresponding portions 500A-500D of an integrated circuit 500, simplified for ease of illustration.

Portion 500A includes one or more features of integrated circuit 500 of the OD level, the POLY level, the CPO level, the MD level, the MDLI level, the VG level and the VD level. Portion 500A is portion 400A. Portion 500A is manufactured by portion 300A.

Portion 500B includes one or more features of integrated circuit 500 of the OD level, the POLY level, the CPO level, the BMD level, the MDLI level, the VDR level, the BVG level and the BVD level. Portion 400B is manufactured by a layout similar to portion 300B, and similar detailed description is omitted for brevity.

Portion 500D includes one or more features of integrated circuit 500 of the BM0 level. Portion 500D is manufactured by a layout similar to portion 300D, and similar detailed description is omitted for brevity.

Portion 500E includes one or more features of integrated circuit 500 of the OD level, the POLY level, the CPO level, the BMD level, the MDLI level, the VDR level, the BVG level, the BVD level and the BM0 level. Portion 500E is manufactured by a layout similar to portion 300F, and similar detailed description is omitted for brevity.

FIG. 5E is a cross-sectional view of integrated circuit 500 as intersected by plane G-G', in accordance with some embodiments.

In some embodiments, integrated circuit 500 is memory cell 200A or 200B.

Integrated circuit 500 is manufactured by a corresponding layout design similar to integrated circuit 500.

In some embodiments, integrated circuit 500 is manufactured by a layout design similar to layout design 300, and similar detailed description is therefore omitted. Structural relationships including alignment, lengths and widths, as well as configurations and layers of integrated circuit 500 are similar to the structural relationships and configurations and layers of integrated circuit 300 of FIGS. 3A-3F, and similar detailed description will not be described in at least FIGS. 5A-5E, for brevity.

Integrated circuit 500 is cell 501.

Integrated circuit 500 is a variation of integrated circuit 400 of FIGS. 4A-4L, and similar detailed description is omitted for brevity.

In comparison with integrated circuit 400 of FIGS. 4A-4L, a set of vias 522 replaces the set of vias 422 of integrated circuit 400, and a set of conductors 532 replaces the set of conductors 432 of integrated circuit 400, and similar detailed description is omitted for brevity.

Integrated circuit 500 includes at least the set of active regions 402 and 404, the set of gates 406 and 408, the set of removed gate portions 440, the set of contacts 410, the set of contacts 412, the set of contacts 414, the set of conductors 416, the set of conductors 430, the set of conductors 532, the set of vias 420, the set of vias 522, the set of vias 424, the set of vias 426, a substrate 490, an insulating region 492 and a set of insulating regions 494.

The set of conductors 532 includes at least one of conductor 432a, 432b, 432c, 432d, 432e or 532f.

In comparison with integrated circuit 400, conductor 532f of the set of conductors 532 is similar to one or more of conductors 432a, 432b, 432c, 432d, 432e of the set of conductors 432, and similar detailed description is omitted for brevity.

The set of conductors 532 is BM0 routing tracks. In some embodiments, the set of conductors 532 is routing tracks in other layers. In some embodiments, the set of conductors 432 corresponds to 5 BM0 routing tracks. Other BM0 track assignments or numbers of BM0 tracks are within the scope of the present disclosure.

In some embodiments, conductor 532f is the read bit line RBL.

Other configurations, arrangements on other layout levels or quantities of conductors in the set of conductors 532 are within the scope of the present disclosure.

The set of vias 522 includes at least one of vias 422a, 422b, 422c or 522d.

In comparison with integrated circuit 400, via 522d of the set of vias 522 is similar to one or more of vias 422a, 422b or 422c of the set of vias 422, and similar detailed description is omitted for brevity.

Via 522f electrically couples conductor 532f and contact 414c together.

In some embodiments, by including conductor 532f in integrated circuit 500, the read bit line RBL is located on both the front-side 403a of integrated circuit 500 as conductor 430e and the back-side 403b of integrated circuit 500 as conductor 532f, thereby improving the speed of integrated circuit 500 compared to other approaches.

In some embodiments, integrated circuit 500 achieves one or more of the benefits described herein.

Other configurations, arrangements on other layout levels or quantities of elements in integrated circuit 500 are within the scope of the present disclosure.

FIG. 6A is a diagram of a portion 600A of a floorplan 600 of an integrated circuit, in accordance with some embodiments.

FIG. 6B is a diagram of a portion 600B of the floorplan 600 of the integrated circuit, in accordance with some embodiments.

In some embodiments, floorplan 600 is a floorplan of integrated circuit 400 of FIGS. 4A-4L or integrated circuit 500 of FIGS. 5A-5E.

In some embodiments, portion 600A is a front-side of integrated circuit 600, in accordance with some embodiments.

In some embodiments, portion 600B is a back-side of integrated circuit 600, in accordance with some embodiments.

Floorplan 600 has two rows extending in a first direction X, and being separated from each other in a second direction Y.

Floorplan 600 includes a cell 601a and a cell 601b.

Cell 601a is located in a row R1.

Cell 601b is located in a row R2. Row R1 is adjacent or next to row R2.

A cell boundary 690 extends in the first direction X. The cell boundary 690 separates cell 601a and cell 601b.

Cell 601a includes a region 602.

Cell 601b includes a region 604.

In some embodiments, cell 601b is a mirror image of cell 601a with respect to cell boundary 690.

In some embodiments, region 602 corresponds to integrated circuit 400 of FIGS. 4A-4L or integrated circuit 500 of FIGS. 5A-5E, and similar detailed description is omitted for brevity.

In some embodiments, region 602 corresponds to layout design 300 of FIGS. 3A-3F, and similar detailed description is omitted for brevity.

In some embodiments, region 604 is a mirror image of region 602 with respect to cell boundary 690.

A region 610a in row R1 includes NFET transistors RPG1 and RPD1.

A region 612a in row R1 includes NFET transistors RPG1 and RPD1. Region 612a is similar to region 610a, and similar detailed description is omitted for brevity.

In some embodiments, the NFET transistors RPG1 and RPD1 of region 612a are included in region 602 to improve the driving strength of the NFET transistors RPG1 and RPD1.

A region 610b in row R2 includes NFET transistors RPG1 and RPD1.

A region 612b in row R2 includes NFET transistors RPG1 and RPD1. Region 612b is similar to region 610b, and similar detailed description is omitted for brevity.

In some embodiments, the NFET transistors RPG1 and RPD1 of region 612a are included in region 602 to improve the driving strength of the NFET transistors RPG1 and RPD1.

A region 620a in row R1 includes PFET transistors RPG2 and RPD2.

A region 622a in row R1 includes PFET transistors RPG2 and RPD2. Region 622a is similar to region 620a, and similar detailed description is omitted for brevity.

In some embodiments, the PFET transistors RPG2 and RPD2 of region 622a are included in region 602 to improve the driving strength of the PFET transistors RPG2 and RPD2.

A region 620b in row R2 includes PFET transistors RPG2 and RPD2.

A region 622b in row R2 includes PFET transistors RPG2 and RPD2. Region 622b is similar to region 620b, and similar detailed description is omitted for brevity.

In some embodiments, the PFET transistors RPG2 and RPD2 of region 622a are included in region 602 to improve the driving strength of the PFET transistors RPG2 and RPD2.

In some embodiments, floorplan 600 of the integrated circuit of FIGS. 6A-6B achieves one or more of the benefits described herein.

Other configurations, arrangements on other layout levels or quantities of elements in floorplan 600 are within the scope of the present disclosure.

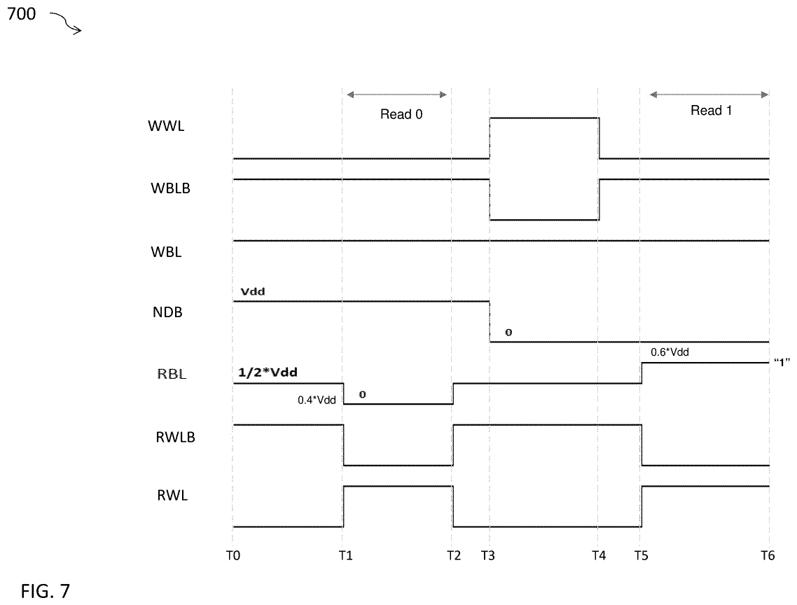

FIG. 7 is a timing diagram 700 of waveforms of a memory cell 200A, in accordance with some embodiments.

In some embodiments, FIG. 7 is a corresponding timing diagram 700 of waveforms of memory circuit 100 in FIG. 1, in accordance with some embodiments.

In some embodiments, timing diagram 700 includes waveforms of signals during a read “0” operation and/or a read “1” operation of memory cell 200A. In some embodiments, the waveforms of signals during a write operation of memory cell 200A are the same as the waveforms of signals during a read operation of memory cell 200A, and are shown as timing diagram 700.

In some embodiments, FIG. 7 is usable as a timing diagram of waveforms of memory cell 200B in FIG. 2B, but in these embodiments the waveforms of word lines and bit lines are changed consistent with the differences with the word lines and bit lines of memory cell 200A in FIG. 2A and memory cell 200B in FIG. 2B, in accordance with some embodiments.

Timing diagram 700 includes waveforms of write word line WWL, write bit line WBL, write bit line bar WBLB, read bit line RBL, read word line RWL, read word line bar RWLB or a signal of storage node NDB.

FIG. 7 is a timing diagram 700 of waveforms of memory circuit 200A in FIG. 2A, in accordance with some embodiments.

At time T0 in FIG. 7, write word line signal WWL is logically low (e.g., reference voltage VSS or “Logic 0”), write bit line bar WBLB is logically high (e.g., voltage VDD or “Logic 1”), write bit line WBL is logically high, the signal of storage node NDB is logically high, read bit line RBL is pre-charged to 0.5*voltage VDD (e.g., VDD/2), read word line bar RWLB is logically high and read word line RWL is logically low.

In some embodiments, a pre-charge voltage of read bit line RBL is equal to 0.5*voltage VDD (e.g., VDD/2). In some embodiments, other pre-charge voltages of the read bit line RBL are within the scope of the present disclosure.

For example, at time T0, PFET transistor RPG2 is turned off in response to read word line bar RWLB being logically high, and NFET transistor RPG1 is turned on in response to read word line RWL being logically being logically low.

For example, at time T0, PFET transistors PU2 and RPD2 are turned off in response to the signal of storage node NDB being logically high, and NFET transistors PD2 and RPD1 are turned on in response to the signal of storage node NDB being logically high.

At time T1 in FIG. 7, the read word line bar signal RWLB transitions from logically high to logically low, thereby causing PFET transistor RPG2 to turn on.

At time T1 in FIG. 7, the read word line signal RWL transitions from logically low to logically high, thereby causing NFET transistor RPG1 to turn on.

At time T1 in FIG. 7, the read bit line RBL transitions from 0.5*VDD to 0.4*VDD in response to PFET transistor RPG2 turning on, and NFET transistor RPG1 turning on.

At time T2 in FIG. 7, the read word line bar signal RWLB transitions from logically low to logically high, thereby causing PFET transistor RPG2 to turn off.

At time T2 in FIG. 7, the read word line signal RWL transitions from logically high to logically low, thereby causing NFET transistor RPG1 to turn off.

At time T2 in FIG. 7, the read bit line RBL transitions from 0.4*VDD to 0.5*VDD in response to PFET transistor RPG2 turning off and NFET transistor RPG1 turning off.

In some embodiments, a read “0” operation of memory cell 200A occurs between time T1 and T2.

In some embodiments, during a read operation of memory cell 200A, when the read bit line RBL is equal to 0.4*VDD corresponds to a logic zero (“0”) or a read “0” from memory cell 200A.

At time T3 in FIG. 7, the write word line signal WWL transitions from logically low to logically high, thereby causing NFET transistors WPG1 and WPG2 to turn on.

At time T3 in FIG. 7, the write bit line bar signal WBLB transitions from logically high to logically low, thereby causing the signal of the storage node NDB to transition from logically high to logically low.

For example, at time T3, PFET transistors PU2 and RPD2 are turned on in response to the signal of storage node NDB transitioning from logically high to logically low, and NFET transistors PD2 and RPD1 are turned off in response to the signal of storage node NDB transitioning from logically high to logically low.

At time T4 in FIG. 7, the write word line signal WWL transitions from logically high to logically low, thereby causing NFET transistors WPG1 and WPG2 to turn off.

At time T4 in FIG. 7, the write bit line bar signal WBLB transitions from logically low to logically high. In some embodiments, at time T4, the signal of the node NDB does not change in response to the write bit line bar signal WBLB transitioning from logically low to logically high since the signal of the node ND is logically high thereby causing NFET transistor PD1 to stay turned on, and causing PFET transistor PU1 to stay turned off.

At time T5 in FIG. 7, the read word line bar signal RWLB transitions from logically high to logically low, thereby causing PFET transistor RPG2 to turn on.

At time T5 in FIG. 7, the read word line signal RWL transitions from logically low to logically high, thereby causing NFET transistor RPG1 to turn on.

At time T5 in FIG. 7, the read bit line RBL transitions from 0.5*VDD to 0.6*VDD in response to PFET transistor RPG2 turning off and NFET transistor RPG1 turning off.

In some embodiments, a read “1” operation of memory cell 200A occurs between time T5 and T6.

In some embodiments, during a read operation of memory cell 200A, when the read bit line RBL is equal to 0.6*VDD corresponds to a logic zero (“1”) or a read “1” from memory cell 200A.

At time T6 in FIG. 7, the write word line signal WWL is logically low, write bit line bar WBLB is logically high, write bit line WBL is logically high, the signal of storage node NDB is logically low, read bit line RBL is equal to 0.6*voltage VDD, read word line bar RWLB is logically low and read word line RWL is logically high.

In some embodiments, NFET transistor RPG1 and PFET transistor RPG2 are configured to receive different corresponding signals (e.g., read word line bar RWLB and read word line RWL) thereby causing NFET transistor RPG1 and PFET transistor RPG2 to be used as separate transistors that are configured to operate independent of each other in a CMOS configuration of at least one read port of a multi-port memory cell, thereby resulting in an integrated circuit 400 or 500 or memory cell 200A or 200B that occupies less area than other approaches.

In some embodiments, by configuring NFET transistor RPG1 and PFET transistor RPG2 to be used as separate transistors and configured to operate independent of each other in a CMOS configuration of at least one read port of a multi-port memory cell, thereby resulting in an integrated circuit 400 or 500 or memory cell 200A or 200B having improved performance and speed compared to other approaches.

In some embodiments, by utilizing timing diagram 700, at least one of memory circuit 200A, memory circuit 200B, integrated circuit 400 or integrated circuit 500 operate to achieve one or more benefits described herein including the details discussed herein.

Other configurations of timing diagram 700 are within the scope of the present disclosure.

FIG. 8 is a functional flow chart of a method 800 of manufacturing an IC device, in accordance with some embodiments. It is understood that additional operations may be performed before, during, and/or after the method 800 depicted in FIG. 8, and that some other processes may only be briefly described herein.

In some embodiments, other order of operations of method 800-1000 is within the scope of the present disclosure. Method 800-1000 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of at least method 800, 900 or 1000 is not performed.

In some embodiments, method 800 is an embodiment of operation 904 of method 900. In some embodiments, the methods 800-1000 are usable to manufacture or fabricate at least integrated circuit 100, 200A, 200B, 400 or 500 or floorplan 600, or an integrated circuit with similar features as at least layout design 300.

In operation 802 of method 800, a first set of transistors and a second set of transistors are fabricated on a front-side 403a of a semiconductor wafer or substrate. In some embodiments, the first set of transistors or the second set of transistors of method 800 includes one or more transistors in at least the set of active regions 402 or 404. In some embodiments, the first set of transistors or the second set of transistors of method 800 includes one or more transistors described herein.

In some embodiments, operation 802 includes fabricating source and drain regions of the set of transistors in a first well. In some embodiments, the first well comprises p-type dopants. In some embodiments, the p-dopants include boron, aluminum or other suitable p-type dopants. In some embodiments, the first well comprises an epi-layer grown over a substrate. In some embodiments, the epi-layer is doped by adding dopants during the epitaxial process. In some embodiments, the epi-layer is doped by ion implantation after the epi-layer is formed. In some embodiments, the first well is formed by doping the substrate. In some embodiments, the doping is performed by ion implantation. In some embodiments, the first well has a dopant concentration ranging from 1×10¹² atoms/cm³ to 1×10¹⁴ atoms/cm³.

In some embodiments, the first well comprises n-type dopants. In some embodiments, the n-type dopants include phosphorus, arsenic or other suitable n-type dopants. In some embodiments, the n-type dopant concentration ranges from about 1×10¹² atoms/cm³ to about 1×10¹⁴ atoms/cm³.

In some embodiments, the formation of the source/drain features includes, a portion of the substrate is removed to form recesses at an edge of spacers, and a filling process is then performed by filling the recesses in the substrate. In some embodiments, the recesses are etched, for example, a wet etching or a dry etching, after removal of a pad oxide layer or a sacrificial oxide layer. In some embodiments, the etch process is performed to remove a top surface portion of the active region adjacent to an isolation region, such as an STI region. In some embodiments, the filling process is performed by an epitaxy or epitaxial (epi) process. In some embodiments, the recesses are filled using a growth process which is concurrent with an etch process where a growth rate of the growth process is greater than an etch rate of the etch process. In some embodiments, the recesses are filled using a combination of growth process and etch process. For example, a layer of material is grown in the recess and then the grown material is subjected to an etch process to remove a portion of the material. Then a subsequent growth process is performed on the etched material until a desired thickness of the material in the recess is achieved. In some embodiments, the growth process continues until a top surface of the material is above the top surface of the substrate. In some embodiments, the growth process is continued until the top surface of the material is co-planar with the top surface of the substrate. In some embodiments, a portion of the first well is removed by an isotropic or an anisotropic etch process. The etch process selectively etches the first well without etching a gate structure and any spacers. In some embodiments, the etch process is performed using a reactive ion etch (RIE), wet etching, or other suitable techniques. In some embodiments, a semiconductor material is deposited in the recesses to form the source/drain features. In some embodiments, an epi process is performed to deposit the semiconductor material in the recesses. In some embodiments, the epi process includes a selective epitaxy growth (SEG) process, CVD process, molecular beam epitaxy (MBE), other suitable processes, and/or combination thereof. The epi process uses gaseous and/or liquid precursors, which interacts with a composition of substrate. In some embodiments, the source/drain features include epitaxially grown silicon (epi Si), silicon carbide, or silicon germanium. Source/drain features of the IC device associated with the gate structure are in-situ doped or undoped during the epi process in some instances. When source/drain features are undoped during the epi process, source/drain features are doped during a subsequent process in some instances. The subsequent doping process is achieved by an ion implantation, plasma immersion ion implantation, gas and/or solid source diffusion, other suitable processes, and/or combination thereof. In some embodiments, source/drain features are further exposed to annealing processes after forming source/drain features and/or after the subsequent doping process.

In some embodiments, operation 802 further includes operation 802a. In some embodiments, operation 802a includes forming a first gate region of the second set of transistors. In some embodiments, the first gate region of the second set of transistors of method 800 includes the set of gates 408.

In some embodiments, operation 802 further includes operation 802b. In some embodiments, operation 802b includes forming a first insulating material on a first gate structure of the second set of transistors. In some embodiments, operation 802b includes forming a first insulating material over at least the first gate structure of the first gate regions of the second set of transistors. In some embodiments, the first gate structure of the first gate regions of the second set of transistors includes at least one of gate 408a1. In some embodiments, the first insulating material includes the set of insulating regions 494. In some embodiments, the first insulating material includes at least one of insulating region 494a.

In some embodiments, operation 802 further includes operation 802c. In some embodiments, operation 802c includes forming a second gate region of the first set of transistors. In some embodiments, the second gate regions of the first set of transistors of method 800 include the set of gates 406.

In some embodiments, the first and second gate region is between the drain region and the source region. In some embodiments, the first and second gate region is over the first well and the substrate. In some embodiments, fabricating the first and second gate regions of operations 802a and 802c include performing one or more deposition processes to form one or more dielectric material layers. In some embodiments, a deposition process includes a chemical vapor deposition (CVD), a plasma enhanced CVD (PECVD), an atomic layer deposition (ALD), or other process suitable for depositing one or more material layers. In some embodiments, fabricating the first and second gate regions includes performing one or more deposition processes to form one or more conductive material layers. In some embodiments, fabricating the first and second gate regions includes forming gate electrodes or dummy gate electrodes. In some embodiments, fabricating the gate regions includes depositing or growing at least one dielectric layer, e.g., gate dielectric. In some embodiments, gate regions are formed using a doped or non-doped polycrystalline silicon (or polysilicon). In some embodiments, the first and second gate regions include a metal, such as Al, Cu, W, Ti, Ta, TiN, TaN, NiSi, CoSi, other suitable conductive materials, or combinations thereof.

In some embodiments, forming the first insulating material on the first gate structure of the second set of transistors of operation 802b includes performing one or more deposition processes to form one or more dielectric material layers and/or insulating material layers. In some embodiments, the one or more deposition processes to form one or more dielectric material layers and/or insulating material layers includes CVD, a PECVD, ALD, or other process suitable for depositing one or more material layers. In some embodiments, forming the first insulating material on the first gate structure of the second set of transistors includes performing one or more deposition processes to form one or more insulating material layers. In some embodiments, the first insulating material is a dielectric material. In some embodiments, the dielectric material includes silicon dioxide, silicon oxy-nitride, or the like.

In some embodiments, operation 802a, 802b and 802c are replaced by forming the first gate regions of the second set of transistors and the second gate regions of the first set of transistors, removing a portion of the first gate regions of the second set of transistors and the second gate regions of the first set of transistors, and forming the first insulating material between the first gate structure of the second set of transistors and the second gate structure of the first set of transistors. In some embodiments, the gate removal process is a POLY cut process that includes one or more etching processes. In some embodiments, the gate removal process includes one or more etching processes suitable to remove a portion of the gate structure. In some embodiments, a mask is used to specify portions of the gate structure that are to be cut or removed. In some embodiments the mask is a hard mask. In some embodiments, the mask is a soft mask. In some embodiments, etching corresponds to plasma etching, reactive ion etching, chemical etching, dry etching, wet etching, other suitable processes, any combination thereof, or the like.

In some embodiments, the gate removal process of operations 802a, 802b or 802c also include the formation of the set of gates 406 or 408, and the cut regions are identified by the set of cut feature patterns 340 of FIGS. 3A-3F.

In some embodiments, operation 802 further includes operation 802d. In some embodiments, operation 802d includes depositing a first conductive material on at least one of a first level, a second level or a third level thereby forming at least one of a corresponding first set of contacts, a second set of contacts or a third set of contacts.

In some embodiments, the first set of contacts, the second set of contacts and the third set of contacts are part of the first set of transistors and the second set of transistors.

In some embodiments, the first set of contacts includes the set of contacts 410.

In some embodiments, the second set of contacts includes the set of contacts 412.

In some embodiments, the third set of contacts includes the set of contacts 414.

In operation 804 of method 800, a first set of vias are formed on the front-side 403a of the a wafer or substrate on a VD level or a VG level (e.g., VD or VG). In some embodiments, the first set of vias of method 800 includes one or more portions at least the set of vias 420 or 424.

In some embodiments, operation 804 includes forming a first set of self-aligned contacts (SACs) in the insulating layer over the front-side 403a of the wafer. In some embodiments, the first set of vias is electrically coupled to at least the first set of transistors or the second set of transistors.

In operation 806 of method 800, a second conductive material is deposited on the front-side 403a of the substrate on a first metal level thereby forming a first set of conductors on the front-side 403a of the wafer or substrate on a first metal level (e.g., M0).

In some embodiments, operation 808 includes at least depositing a first set of conductive regions over the front-side 403a of the integrated circuit. In some embodiments, the first set of conductors of method 800 includes one or more portions of at least the set of conductors 430.

In some embodiments, the first set of conductors includes a first read word line (RWL/430f) and a first read bit line (RBL/430e). In some embodiments, the first set of transistors s configured to receive a first read word line signal on the first read word line (RWL) and a first read bit line signal on the first read bit line (RBL) from the front-side.

In operation 808 of method 800, thinning is performed on the back-side 403b of the wafer or substrate. In some embodiments, operation 810 includes a thinning process performed on the back-side 403b of the semiconductor wafer or substrate. In some embodiments, the thinning process includes a grinding operation and a polishing operation (such as chemical mechanical polishing (CMP)) or other suitable processes. In some embodiments, after the thinning process, a wet etching operation is performed to remove defects formed on the back-side 403b of the semiconductor wafer or substrate.

In operation 810 of method 800, a second set of conductors (VDR/416) is fabricated in the back-side of the thinned wafer.

In some embodiments, the second set of conductors is below one or more gates (e.g., set of gates 406 or 408) or active regions (e.g., set of active region 402 or 404) of at least the first set of transistors or the second set of transistors.

In some embodiments, the second set of conductors is electrically coupled to at least the second set of transistors. In some embodiments, the second set of conductors is embedded in the thinned substrate.

In some embodiments, the second set of conductors of method 800 includes one or more portions of at least the set of conductors 416.

In operation 812 of method 800, a second set of vias are formed on the back-side 403b of the thinned wafer or substrate on a BVD level or a BVG level (e.g., BVD or BVG). In some embodiments, the second set of vias of method 800 includes one or more portions at least the set of vias 422, 426 or 522.

In some embodiments, operation 812 includes forming a second set of self-aligned contacts (SACs) in the insulating layer over the back-side 403b of the wafer. In some embodiments, the second set of vias is electrically coupled to at least the first set of transistors or the second set of transistors.

In operation 814 of method 800, a third conductive material is deposited on the back-side 403b of the substrate on a second metal level thereby forming a third set of conductors on the back-side 403b of the wafer or substrate on the second metal level (e.g., BM0).

In some embodiments, operation 814 includes at least depositing a second set of conductive regions over the back-side 403b of the integrated circuit. In some embodiments, the third set of conductors of method 800 includes one or more portions of at least the set of conductors 432 or 532.

In some embodiments, the third set of conductors is electrically coupled to at least the second set of transistors by the second set of vias. In some embodiments, the second set of conductors comprising a second read word line (RWL/432e). In some embodiments, the second set of transistors is configured to receive a second read word line signal on the second read word line.

In some embodiments, the second set of conductors further comprises a second read bit line (RBL/532f). In some embodiments, the second set of transistors is further configured to receive the first read bit line signal on the second read bit line from the back-side.

In some embodiments, one or more of operations 802, 804, 806, 810, 812 or 814 of method 800 include using a combination of photolithography and material removal processes to form openings in an insulating layer (not shown) over the substrate. In some embodiments, the photolithography process includes patterning a photoresist, such as a positive photoresist or a negative photoresist. In some embodiments, the photolithography process includes forming a hard mask, an antireflective structure, or another suitable photolithography structure. In some embodiments, the material removal process includes a wet etching process, a dry etching process, an RIE process, laser drilling or another suitable etching process. The openings are then filled with conductive material, e.g., copper, aluminum, titanium, nickel, tungsten, or other suitable conductive material. In some embodiments, the openings are filled using CVD, PVD, sputtering, ALD or other suitable formation process.

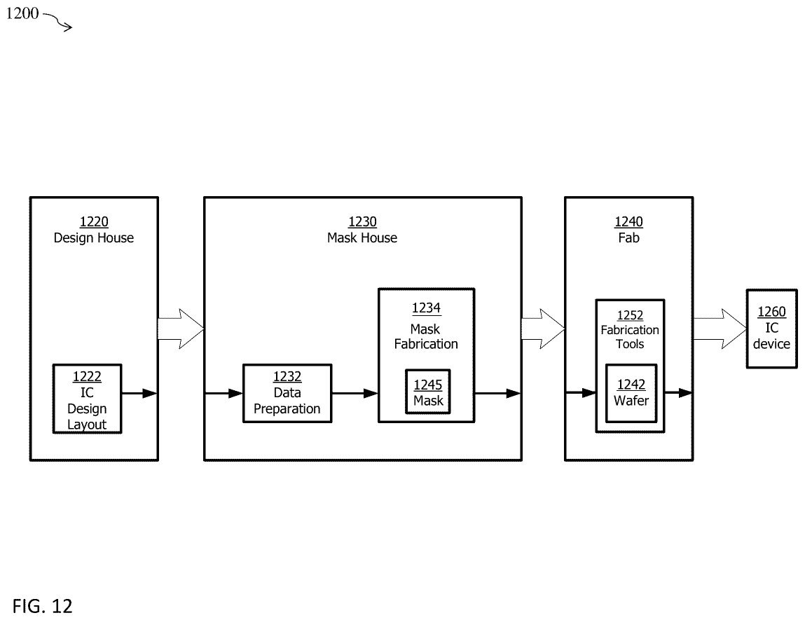

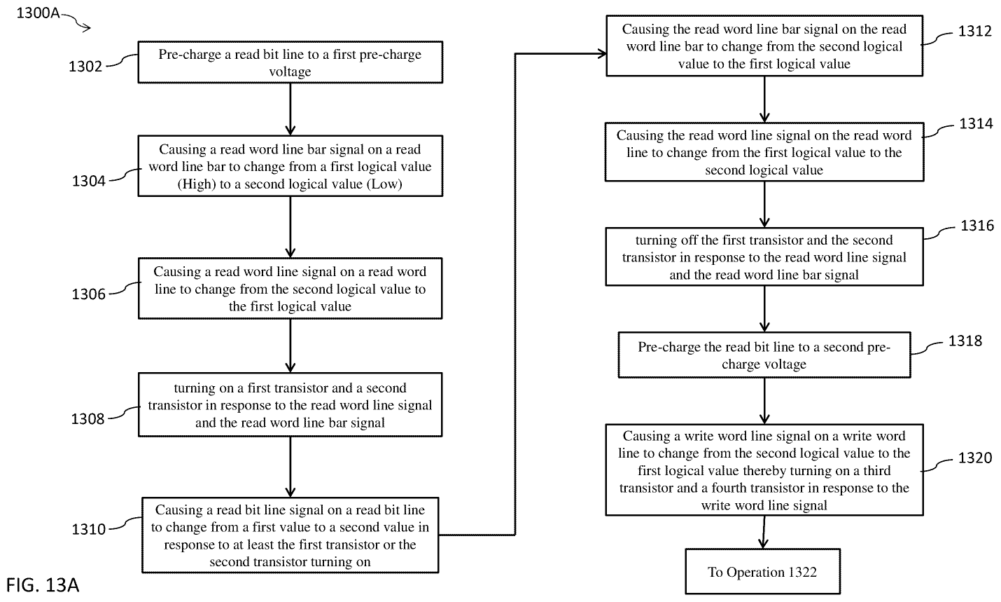

In some embodiments, at least one or more operations of method 800 is performed by system 1200 of FIG. 12. In some embodiments, at least one method(s), such as method 800 discussed above, is performed in whole or in part by at least one manufacturing system, including system 1200. One or more of the operations of method 800 is performed by IC fab 1240 (FIG. 12) to fabricate IC device 1260. In some embodiments, one or more of the operations of method 800 is performed by fabrication tools 1252 to fabricate wafer 1242.

In some embodiments, the conductive material includes copper, aluminum, titanium, nickel, tungsten, or other suitable conductive material. In some embodiments, the openings and trench are filled using CVD, PVD, sputtering, ALD or other suitable formation process. In some embodiments, after conductive material is deposited in one or more of operations 802d, 806, 808 or 814, the conductive material is planarized to provide a level surface for subsequent steps.

In some embodiments, one or more of the operations of method 800, 900 or 1000 is not performed.

One or more of the operations of methods 800-900 is performed by a processing device configured to execute instructions for manufacturing an integrated circuit, such as at least integrated circuit 100, 200A, 200B, 400 or 500 or floorplan 600. In some embodiments, one or more operations of methods 800-900 are performed using a same processing device as that used in a different one or more operations of methods 800-900. In some embodiments, a different processing device is used to perform one or more operations of methods 800-900 from that used to perform a different one or more operations of methods 800-900. In some embodiments, other order of operations of method 800, 900 or 1000 is within the scope of the present disclosure. Method 800, 900 or 1000 includes exemplary operations, but the operations are not necessarily performed in the order shown. Operations in method 800, 900 or 1000 may be added, replaced, changed order, and/or eliminated as appropriate, in accordance with the spirit and scope of disclosed embodiments.

FIG. 9 is a flowchart of a method 900 of forming or manufacturing an integrated circuit in accordance with some embodiments. It is understood that additional operations may be performed before, during, and/or after the method 900 depicted in FIG. 9, and that some other operations may only be briefly described herein. In some embodiments, the method 900 is usable to form integrated circuits, such as at least integrated circuit 100, 200A, 200B, 400 or 500. In some embodiments, the method 900 is usable to form integrated circuits having similar features and similar structural relationships as one or more of layout design 300.

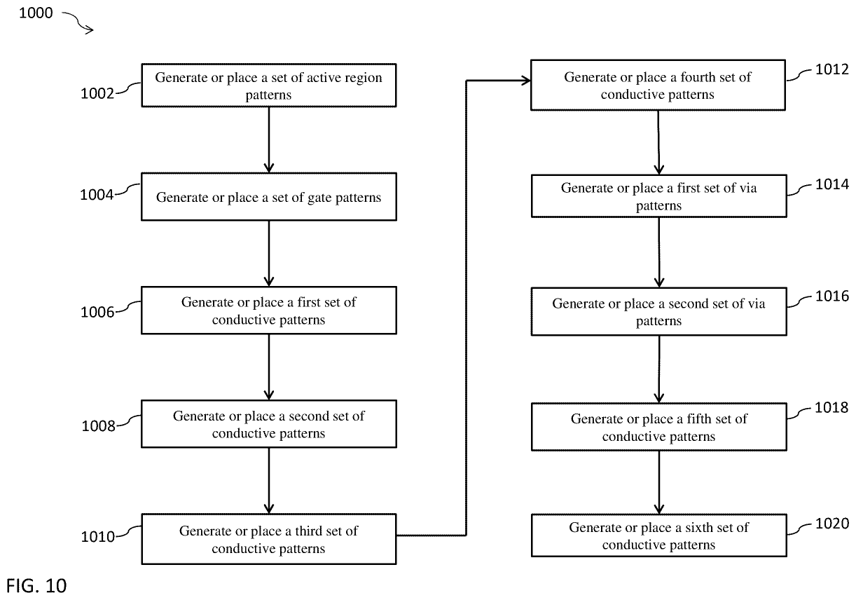

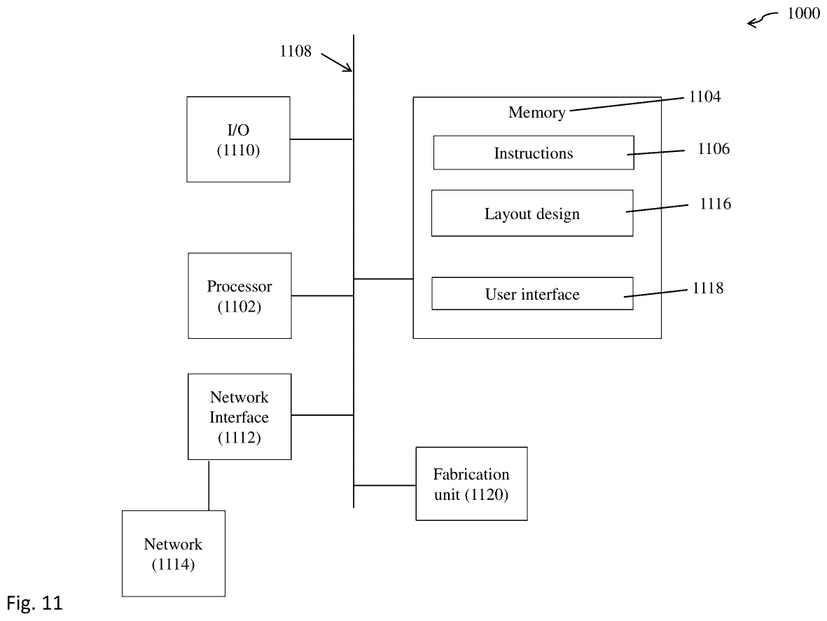

In operation 902 of method 900, a layout design of an integrated circuit is generated. Operation 902 is performed by a processing device (e.g., processor 1102 (FIG. 11)) configured to execute instructions for generating a layout design. In some embodiments, the layout design of method 900 includes one or more patterns of at least layout design 300, or one or more features similar to at least integrated circuit 100, 200A, 200B, 400 or 500 or floorplan 600. In some embodiments, the layout design of the present application is in a graphic database system (GDSII) file format. In some embodiments, operation 902 corresponds to method 1000 of FIG. 10.

In operation 904 of method 900, the integrated circuit is manufactured based on the layout design. In some embodiments, operation 904 of method 900 comprises manufacturing at least one mask based on the layout design, and manufacturing the integrated circuit based on the at least one mask. In some embodiments, operation 904 corresponds to method 800 of FIG. 8.

FIG. 10 is a flowchart of a method 1000 of generating a layout design of an integrated circuit, in accordance with some embodiments. It is understood that additional operations may be performed before, during, and/or after the method 1000 depicted in FIG. 10, and that some other processes may only be briefly described herein. In some embodiments, method 1000 is an embodiment of operation 1002 of method 900. In some embodiments, method 1000 is usable to generate one or more layout patterns of at least layout design 300, or one or more features similar to at least integrated circuit 100, 200A, 200B, 400 or 500 or floorplan 600.

In some embodiments, method 1000 is usable to generate one or more layout patterns having structural relationships including alignment, lengths and widths, as well as configurations and layers of at least layout design 300, or one or more features similar to at least integrated circuit 100, 200A, 200B, 400 or 500 or floorplan 600, and similar detailed description will not be described in FIG. 10, for brevity.

In operation 1002 of method 1000, a set of active region patterns is generated or placed on the layout design. In some embodiments, the set of active region patterns of method 1000 includes at least portions of one or more patterns of the set of active region patterns 302 or 304. In some embodiments, the set of active region patterns of method 1000 includes one or more regions similar to the set of active regions 402 or 404. In some embodiments, the set of active region patterns of method 1000 includes one or more patterns or similar patterns in the OD layer.

In operation 1004 of method 1000, a set of gate patterns is generated or placed on the layout design. In some embodiments, the set of gate patterns of method 1000 includes at least portions of one or more patterns of the set of gate patterns 306 or 308 or the set of cut feature patterns 340. In some embodiments, the set of active gate patterns of method 1000 includes one or more regions similar to the set of gates 406 or 408. In some embodiments, the set of gate patterns of method 1000 includes at least portions of one or more patterns of the set of insulating patterns 394. In some embodiments, the set of gate patterns of method 1000 includes one or more regions similar to the set of insulating regions 494. In some embodiments, the set of gate patterns of method 1000 includes one or more patterns or similar patterns in the POLY layer.

In operation 1006 of method 1000, a first set of conductive patterns is generated or placed on the layout design. In some embodiments, the first set of conductive patterns of method 1000 includes at least portions of one or more patterns of the set of contact patterns 310. In some embodiments, the first set of conductive patterns of method 1000 includes one or more patterns similar to the set of contacts 410. In some embodiments, the first set of conductive patterns of method 1000 includes one or more patterns or similar patterns in the MD layer.

In operation 1008 of method 1000, a second set of conductive patterns is generated or placed on the layout design. In some embodiments, the second set of conductive patterns of method 1000 includes at least portions of one or more patterns of the set of contact patterns 312. In some embodiments, the second set of conductive patterns of method 1000 includes one or more patterns similar to the set of contacts 412. In some embodiments, the second set of conductive patterns of method 1000 includes one or more patterns or similar patterns in the BMD layer.

In operation 1010 of method 1000, a third set of conductive patterns is generated or placed on the layout design. In some embodiments, the third set of conductive patterns of method 1000 includes at least portions of one or more patterns of the set of contact patterns 314. In some embodiments, the third set of conductive patterns of method 1000 includes one or more patterns similar to the set of contacts 414. In some embodiments, the third set of conductive patterns of method 1000 includes one or more patterns or similar patterns in the MDLI layer.

In operation 1012 of method 1000, a fourth set of conductive patterns is generated or placed on the layout design. In some embodiments, the fourth set of conductive patterns of method 1000 includes at least portions of one or more patterns of the set of conductive feature patterns 316. In some embodiments, the fourth set of conductive patterns of method 1000 includes one or more patterns similar to the set of conductors 416. In some embodiments, the fourth set of conductive patterns of method 1000 includes one or more patterns or similar patterns in the VDR layer.

In operation 1014 of method 1000, a first set of via patterns is generated or placed on the layout design. In some embodiments, the first set of via patterns of method 1000 includes at least portions of one or more patterns of the set of via patterns 320 or 324. In some embodiments, the first set of via patterns of method 1000 includes one or more via patterns similar to at least the set of vias 420 or 424. In some embodiments, the first set of via patterns of method 1000 includes one or more patterns or similar vias in the VG or VD layer.

In operation 1016 of method 1000, a second set of via patterns is generated or placed on the layout design. In some embodiments, the second set of via patterns of method 1000 includes at least portions of one or more patterns of the set of via patterns 322 or 326. In some embodiments, the second set of via patterns of method 1000 includes one or more via patterns similar to at least the set of vias 422, 426 or 522. In some embodiments, the second set of via patterns of method 1000 includes one or more patterns or similar vias in the BVG or BVD layer.

In operation 1018 of method 1000, a fifth set of conductive patterns is generated or placed on the layout design. In some embodiments, the fifth set of conductive patterns of method 1000 includes at least portions of one or more patterns of at least the set of conductive patterns 330. In some embodiments, the fifth set of conductive patterns of method 1000 includes one or more conductive patterns similar to at least the set of conductors 430. In some embodiments, the fifth set of conductive patterns of method 1000 includes one or more patterns or similar conductors in the M0 layer.

In operation 1020 of method 1000, a sixth set of conductive patterns is generated or placed on the layout design. In some embodiments, the sixth set of conductive patterns of method 1000 includes at least portions of one or more patterns of at least the set of conductive patterns 332. In some embodiments, the sixth set of conductive patterns of method 1000 includes one or more conductive patterns similar to at least the set of conductors 432 or 532. In some embodiments, the sixth set of conductive patterns of method 1000 includes one or more patterns or similar conductors in the BM0 layer.

FIG. 11 is a schematic view of a system 1100 for designing an IC layout design and manufacturing an IC circuit in accordance with some embodiments.

In some embodiments, system 1100 generates or places one or more IC layout designs described herein. System 1100 includes a hardware processor 1102 and a non-transitory, computer readable storage medium 1104 (e.g., memory 1104) encoded with, i.e., storing, the computer program code 1106, i.e., a set of executable instructions 1106. Computer readable storage medium 1104 is configured for interfacing with manufacturing machines for producing the integrated circuit. The processor 1102 is electrically coupled to the computer readable storage medium 1104 via a bus 1108. The processor 1102 is also electrically coupled to an I/O interface 1110 by bus 1108. A network interface 1112 is also electrically connected to the processor 1102 via bus 1108. Network interface 1112 is connected to a network 1114, so that processor 1102 and computer readable storage medium 1104 are capable of connecting to external elements via network 1114. The processor 1102 is configured to execute the computer program code 1106 encoded in the computer readable storage medium 1104 in order to cause system 1100 to be usable for performing a portion or all of the operations as described in method 900-1000.

In some embodiments, the processor 1102 is a central processing unit (CPU), a multi-processor, a distributed processing system, an application specific integrated circuit (ASIC), and/or a suitable processing unit.

In some embodiments, the computer readable storage medium 1104 is an electronic, magnetic, optical, electromagnetic, infrared, and/or a semiconductor system (or apparatus or device). For example, the computer readable storage medium 1104 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 1104 includes a compact disk-read only memory (CD-ROM), a compact disk-read/write (CD-R/W), and/or a digital video disc (DVD).

In some embodiments, the storage medium 1104 stores the computer program code 1106 configured to cause system 1100 to perform method 900-1000. In some embodiments, the storage medium 1104 also stores information needed for performing method 900-1000 as well as information generated during performing method 900-1000, such as layout design 1116, user interface 1118 and fabrication unit 1120, and/or a set of executable instructions to perform the operation of method 900-1000. In some embodiments, layout design 1116 comprises one or more of layout patterns of at least layout design 300, or features similar to at least integrated circuit 100, 200A, 200B, 400 or 500 or floorplan 600.

In some embodiments, the storage medium 1104 stores instructions (e.g., computer program code 1106) for interfacing with manufacturing machines. The instructions (e.g., computer program code 1106) enable processor 1102 to generate manufacturing instructions readable by the manufacturing machines to effectively implement method 900-1000 during a manufacturing process.

System 1100 includes I/O interface 1110. I/O interface 1110 is coupled to external circuitry. In some embodiments, I/O interface 1110 includes a keyboard, keypad, mouse, trackball, trackpad, and/or cursor direction keys for communicating information and commands to processor 1102.

System 1100 also includes network interface 1112 coupled to the processor 1102. Network interface 1112 allows system 1100 to communicate with network 1114, to which one or more other computer systems are connected. Network interface 1112 includes wireless network interfaces such as BLUETOOTH, WIFI, WIMAX, GPRS, or WCDMA; or wired network interface such as ETHERNET, USB, or IEEE-2094. In some embodiments, method 900-1000 is implemented in two or more systems 1100, and information such as layout design, and user interface are exchanged between different systems 1100 by network 1114.

System 1100 is configured to receive information related to a layout design through I/O interface 1110 or network interface 1112. The information is transferred to processor 1102 by bus 1108 to determine a layout design for producing at least integrated circuit 100, 200A, 200B, 400 or 500 or floorplan 600. The layout design is then stored in computer readable medium 1104 as layout design 1116. System 1100 is configured to receive information related to a user interface through I/O interface 1110 or network interface 1112. The information is stored in computer readable medium 1104 as user interface 1118. System 1100 is configured to receive information related to a fabrication unit 1120 through I/O interface 1110 or network interface 1112. The information is stored in computer readable medium 1104 as fabrication unit 1120. In some embodiments, the fabrication unit 1120 includes fabrication information utilized by system 1100. In some embodiments, the fabrication unit 1120 corresponds to mask fabrication 1234 of FIG. 12.

In some embodiments, method 900-1000 is implemented as a standalone software application for execution by a processor. In some embodiments, method 900-1000 is implemented as a software application that is a part of an additional software application. In some embodiments, method 900-1000 is implemented as a plug-in to a software application. In some embodiments, method 900-1000 is implemented as a software application that is a portion of an EDA tool. In some embodiments, method 900-1000 is implemented as a software application that is used by an EDA tool. In some embodiments, the EDA tool is used to generate a layout of the integrated circuit device. In some embodiments, the layout is stored on a non-transitory computer readable medium. In some embodiments, the layout is generated using a tool such as VIRTUOSO® available from CADENCE DESIGN SYSTEMS, Inc., or another suitable layout generating tool. In some embodiments, the layout is generated based on a netlist which is created based on the schematic design. In some embodiments, method 900-1000 is implemented by a manufacturing device to manufacture an integrated circuit using a set of masks manufactured based on one or more layout designs generated by system 1100. In some embodiments, system 1100 is a manufacturing device configured to manufacture an integrated circuit using a set of masks manufactured based on one or more layout designs of the present disclosure. In some embodiments, system 1100 of FIG. 11 generates layout designs of an integrated circuit that are smaller than other approaches. In some embodiments, system 1100 of FIG. 11 generates layout designs of integrated circuit structure that occupy less area and provide better routing resources than other approaches.

FIG. 12 is a block diagram of an integrated circuit (IC) manufacturing system 1200, and an IC manufacturing flow associated therewith, in accordance with at least one embodiment of the present disclosure. In some embodiments, based on a layout diagram, at least one of (A) one or more semiconductor masks or (B) at least one component in a layer of a semiconductor integrated circuit is fabricated using manufacturing system 1200.

In FIG. 12, IC manufacturing system 1200 (hereinafter “system 1200”) includes entities, such as a design house 1220, a mask house 1230, and an IC manufacturer/fabricator (“fab”) 1240, that interact with one another in the design, development, and manufacturing cycles and/or services related to manufacturing an IC device 1260. The entities in system 1200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, one or more of design house 1220, mask house 1230, and IC fab 1240 is owned by a single larger company. In some embodiments, one or more of design house 1220, mask house 1230, and IC fab 1240 coexist in a common facility and use common resources.

Design house (or design team) 1220 generates an IC design layout 1222. IC design layout 1222 includes various geometrical patterns designed for an IC device 1260. The geometrical patterns correspond to patterns of metal, oxide, or semiconductor layers that make up the various components of IC device 1260 to be fabricated. The various layers combine to form various IC features. For example, a portion of IC design layout 1222 includes various IC features, such as an active region, gate electrode, source electrode and drain electrode, metal lines or vias of an interlayer interconnection, and openings for bonding pads, to be formed in a semiconductor substrate (such as a silicon wafer) and various material layers disposed on the semiconductor substrate. Design house 1220 implements a proper design procedure to form IC design layout 1222. The design procedure includes one or more of logic design, physical design or place and route. IC design layout 1222 is presented in one or more data files having information of the geometrical patterns. For example, IC design layout 1222 can be expressed in a GDSII file format or DFII file format.

Mask house 1230 includes data preparation 1232 and mask fabrication 1234. Mask house 1230 uses IC design layout 1222 to manufacture one or more masks 1245 to be used for fabricating the various layers of IC device 1260 according to IC design layout 1222. Mask house 1230 performs mask data preparation 1232, where IC design layout 1222 is translated into a representative data file (RDF). Mask data preparation 1232 provides the RDF to mask fabrication 1234. Mask fabrication 1234 includes a mask writer. A mask writer converts the RDF to an image on a substrate, such as a mask (reticle) 1245 or a semiconductor wafer 1242. The IC design layout 1222 is manipulated by mask data preparation 1232 to comply with particular characteristics of the mask writer and/or requirements of IC fab 1240. In FIG. 12, mask data preparation 1232 and mask fabrication 1234 are illustrated as separate elements. In some embodiments, mask data preparation 1232 and mask fabrication 1234 can be collectively referred to as mask data preparation.

In some embodiments, mask data preparation 1232 includes optical proximity correction (OPC) which uses lithography enhancement techniques to compensate for image errors, such as those that can arise from diffraction, interference, other process effects and the like. OPC adjusts IC design layout 1222. In some embodiments, mask data preparation 1232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1232 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 1234, which may undo part of the modifications performed by OPC in order to meet mask creation rules.

In some embodiments, mask data preparation 1232 includes lithography process checking (LPC) that simulates processing that will be implemented by IC fab 1240 to fabricate IC device 1260. LPC simulates this processing based on IC design layout 1222 to create a simulated manufactured device, such as IC device 1260. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 1222.

It should be understood that the above description of mask data preparation 1232 has been simplified for the purposes of clarity. In some embodiments, data preparation 1232 includes additional features such as a logic operation (LOP) to modify the IC design layout according to manufacturing rules. Additionally, the processes applied to IC design layout 1222 during data preparation 1232 may be executed in a variety of different orders.

After mask data preparation 1232 and during mask fabrication 1234, a mask 1245 or a group of masks 1245 are fabricated based on the modified IC design layout 1222. In some embodiments, mask fabrication 1234 includes performing one or more lithographic exposures based on IC design layout 1222. In some embodiments, an electron-beam (e-beam) or a mechanism of multiple e-beams is used to form a pattern on a mask (photomask or reticle) 1245 based on the modified IC design layout 1222. The mask 1245 can be formed in various technologies. In some embodiments, the mask 1245 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary version of mask 1245 includes a transparent substrate (e.g., fused quartz) and an opaque material (e.g., chromium) coated in the opaque regions of the binary mask. In another example, the mask 1245 is formed using a phase shift technology. In the phase shift mask (PSM) version of mask 1245, various features in the pattern formed on the mask are configured to have proper phase difference to enhance the resolution and imaging quality. In various examples, the phase shift mask can be attenuated PSM or alternating PSM. The mask(s) generated by mask fabrication 1234 is used in a variety of processes. For example, such a mask(s) is used in an ion implantation process to form various doped regions in the semiconductor wafer, in an etching process to form various etching regions in the semiconductor wafer, and/or in other suitable processes.

IC fab 1240 is an IC fabrication entity that includes one or more manufacturing facilities for the fabrication of a variety of different IC products. In some embodiments, IC Fab 1240 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry entity.

IC fab 1240 includes wafer fabrication tools 1252 (hereinafter “fabrication tools 1252”) configured to execute various manufacturing operations on semiconductor wafer 1242 such that IC device 1260 is fabricated in accordance with the mask(s), e.g., mask 1245. In various embodiments, fabrication tools 1252 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1240 uses mask(s) 1245 fabricated by mask house 1230 to fabricate IC device 1260. Thus, IC fab 1240 at least indirectly uses IC design layout 1222 to fabricate IC device 1260. In some embodiments, a semiconductor wafer 1242 is fabricated by IC fab 1240 using mask(s) 1245 to form IC device 1260. In some embodiments, the IC fabrication includes performing one or more lithographic exposures based at least indirectly on IC design 1222. Semiconductor wafer 1242 includes a silicon substrate or other proper substrate having material layers formed thereon. Semiconductor wafer 1242 further includes one or more of various doped regions, dielectric features, multilevel interconnects, and the like (formed at subsequent manufacturing steps).

System 1200 is shown as having design house 1220, mask house 1230 or IC fab 1240 as separate components or entities. However, it is understood that one or more of design house 1220, mask house 1230 or IC fab 1240 are part of the same component or entity.

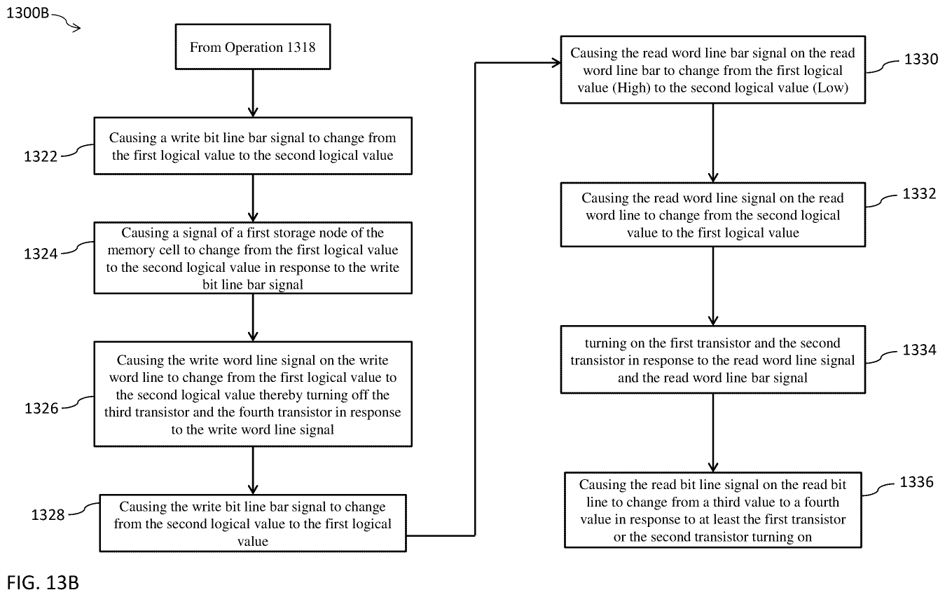

FIGS. 13A-13B are a flowchart of a method of operating a circuit, in accordance with some embodiments.

FIGS. 13A-13B are a flowchart of method 1300 of operating a circuit, in accordance with some embodiments.

In some embodiments, FIGS. 13A-13B are a flowchart of method 1300 of operating at least one of memory cell 200A of FIG. 2A or memory cell 200B of FIG. 2B. For example, in some embodiments, FIGS. 13A-13B are a flowchart of method 1300 of performing at least one of a read “0” operation or read “1” operation of at least one of memory cell 200A of FIG. 2A or memory cell 200B of FIG. 2B.

In some embodiments, FIGS. 13A-13B are a flowchart of method 1300 of operating at least one of memory circuit 100 of FIG. 1, integrated circuit 400 of FIGS. 4A-4L, integrated circuit 500 of FIGS. 5A-5E or floorplan 600 of FIGS. 6A-6B.

In some embodiments, FIGS. 13A-13B are a flowchart of method 1300 of operating a memory circuit, and the method 1300 includes the features of timing diagram 700 of FIG. 7, and similar detailed description is omitted for brevity.

It is understood that additional operations may be performed before, during, and/or after method 1300 depicted in FIGS. 13A-13B, and that some other operations may only be briefly described herein. It is understood that method 1300 utilizes features of one or more of least one of memory circuit 100 of FIG. 1, memory cell 200A of FIG. 2A, memory cell 200B of FIG. 2B, layout design 300 of FIGS. 3A-3F, integrated circuit 400 of FIGS. 4A-4L, integrated circuit 500 of FIGS. 5A-5E, or floorplan 600 of FIGS. 6A-6B, and similar detailed description is omitted for brevity.

In some embodiments, other order of operations of method 1300 are within the scope of the present disclosure. Method 1300 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of method 1300 is not performed.

In some embodiments, common elements in method 1300 are not labelled in the description of each individual method 1300 for brevity.

In operation 1302 of method 1300, a read bit line is pre-charged to a first pre-charge voltage.

In some embodiments, the first pre-charge voltage is equal to 0.5*VDD. Other pre-charge voltages are within the scope of the present disclosure.

In some embodiments, the read bit line includes read bit line RBL.

In operation 1304 of method 1300, a read word line bar signal on a read word line bar is caused to change from a first logical value (High) to a second logical value (Low).

In some embodiments, the first logical value is a logic 1, and the second logical value is a logic 0.

In some embodiments, the read word line bar includes the read word line bar RWLB.

In some embodiments, at least one or more of operations 1302-1336 is performed by at least one of the word line driver 110ac or LIO circuit 110BS.

In operation 1306 of method 1300, a read word line signal on a read word line is caused to change from the second logical value to the first logical value.

In some embodiments, the read word line includes the read word line RWL.

In operation 1308 of method 1300, a first transistor and a second transistor are turned on in response to the read word line bar signal In some embodiments, the first transistor includes NFET transistor RPG1, and the second transistor includes PFET transistor RPG2.

In operation 1310 of method 1300, a read bit line signal on a read bit line is caused to change from a first value to a second value in response to at least the first transistor or the second transistor turning on.

In some embodiments, the read bit line includes the read bit line RBL.

In some embodiments, the first value is equal to 0.5*VDD.

In some embodiments, the second value is equal to 0.4*VDD.

Other values for the first value or the second value are within the scope of the present disclosure.

In operation 1312 of method 1300, the read word line bar signal on the read word line bar is caused to change from the second logical value to the first logical value.

In operation 1314 of method 1300, the read word line signal on the read word line is caused to change from the first logical value to the second logical value.

In operation 1316 of method 1300, the first transistor and the second transistor are turned off in response to the read word line signal and the read word line bar signal.

In operation 1318 of method 1300, the read bit line is pre-charged to a second pre-charge voltage.

In some embodiments, the second pre-charge voltage is equal to 0.5*VDD. Other pre-charge voltages are within the scope of the present disclosure.

In operation 1320 of method 1300, a write word line signal on a write word line is caused to change from the second logical value to the first logical value thereby turning on a third transistor and a fourth transistor in response to the write word line signal.

In some embodiments, the third transistor includes NFET transistor WPG1, and the fourth transistor includes NFET transistor WPG2.

In some embodiments, the write word line includes the write word line WWL.

In operation 1322 of method 1300, a write bit line bar signal on a write bit line is caused to change from the first logical value to the second logical value In some embodiments, the write bit line bar includes the write bit line bar WBLB.

In operation 1324 of method 1300, a signal of a first storage node of the memory cell is caused to change from the first logical value to the second logical value in response to the write bit line bar signal.

In some embodiments, the first storage node of the memory cell is storage node NQB.

In operation 1326 of method 1300, the write word line signal on the write word line is caused to change from the first logical value to the second logical value thereby turning off the third transistor and the fourth transistor in response to the write word line signal.

In operation 1328 of method 1300, the write bit line bar signal is caused to change from the second logical value to the first logical value.

In operation 1330 of method 1300, the read word line bar signal on the read word line bar is caused to change from the first logical value (High) to the second logical value (Low).

In operation 1332 of method 1300, the read word line signal on the read word line is caused to change from the second logical value to the first logical value.

In operation 1334 of method 1300, the first transistor and the second transistor are turned on in response to the read word line signal and the read word line bar signal.

In operation 1336 of method 1300, the read bit line signal on the read bit line is caused to change from a third value to a fourth value in response to at least the first transistor or the second transistor turning on.

In some embodiments, the third value is equal to 0.5*VDD.

In some embodiments, the fourth value is equal to 0.6*VDD.

Other values for the third value or the fourth value are within the scope of the present disclosure.

By operating method 1300, the circuit operates to achieve the benefits discussed herein.

In some embodiments, one or more of the operations of method 1300 is not performed. Furthermore, various PFET or NFET transistors shown in the present disclosure are of a particular dopant type (e.g., N-type or P-type) are for illustration purposes. Embodiments of the disclosure are not limited to a particular transistor type, and one or more of the PFET or NFET transistors shown in the present disclosure can be substituted with a corresponding transistor of a different transistor/dopant type. Similarly, the low or high logical value of various signals used in the above description is also for illustration. Embodiments of the disclosure are not limited to a particular logical value when a signal is activated and/or deactivated. Selecting different logical values is within the scope of various embodiments. Selecting different numbers of transistors in the present disclosure is within the scope of various embodiments.

One aspect of this description relates to a device. In some embodiments, the device is a multi-port memory cell. In some embodiments, the device includes a cross-latch including a first storage node and a second storage node. In some embodiments, the device includes a first transistor of a first type, the first transistor including a first gate extending in a first direction, and being on a first level. In some embodiments, the device includes a second transistor of a second type different from the first type, and the second transistor including a second gate on a second level below the first level. In some embodiments, the device includes a third transistor of the first type, and being coupled to the first storage node, the third transistor including a third gate on the first level. In some embodiments, the device includes a fourth transistor of the second type, and being coupled to the first storage node, the fourth transistor including a fourth gate on the second level. In some embodiments, the device includes a first read bit line extending in a second direction different from the first direction, the first read bit line being on a first metal layer above a front-side of a substrate, and being coupled to the third transistor and the fourth transistor. In some embodiments, the third transistor and the fourth transistor correspond to at least a first port of the device.

Another aspect of this description relates to a device. In some embodiments, the device is a multi-port memory cell. In some embodiments, the device includes a pair of inverters coupled to a first storage node and a second storage node. In some embodiments, the device further includes a first transistor stack on a substrate. In some embodiments, the first transistor stack includes a first transistor of a first type, the first transistor including a first gate extending in a first direction, and being on a first level. In some embodiments, the first transistor stack further includes a second transistor of a second type different from the first type, and the second transistor including a second gate extending in the first direction, and being on a second level below the first level. In some embodiments, the device further includes a second transistor stack on the substrate. In some embodiments, the second transistor stack includes a third transistor of the first type, and being coupled to the first storage node, the third transistor including a third gate extending in the first direction, and being on the first level. In some embodiments, the second transistor stack further includes a fourth transistor of the second type, and being coupled to the first storage node, the fourth transistor including a fourth gate extending in the first direction, and being on the second level. In some embodiments, the device further includes a first conductor extending in a second direction different from the first direction, the first conductor being on a first metal layer above a front-side of the substrate, being coupled to the third transistor and the fourth transistor, and being configured as a first read bit line. In some embodiments, the device further includes a second conductor configured as a second read bit line extending in the second direction different from the first direction, the second conductor being on a second metal layer below a back-side of the substrate, and being coupled to the third transistor and the fourth transistor, and the second metal layer being different from the first metal layer.

Still another aspect of this description relates to a method of fabricating a device. In some embodiments, the device is a multi-port memory cell. In some embodiments, the method includes fabricating a first set of transistors and a second set of transistors in a front-side of a substrate, the first set of transistors being stacked above the second set of transistors. In some embodiments, the method further includes fabricating a first set of vias on the front-side of the substrate, the first set of vias being electrically coupled to at least the first set of transistors. In some embodiments, the method further includes depositing a first conductive material on the front-side of the substrate on a first metal level thereby forming a first set of conductors, the first set of conductors being electrically coupled to at least the first set of transistors by the first set of vias, the first set of conductors including a first read word line and a first read bit line, the first set of transistors being configured to receive a first read word line signal on the first read word line and a first read bit line signal on the first read bit line from the front-side. In some embodiments, the method further includes performing thinning on a back-side of the substrate opposite from the front-side. In some embodiments, the method further includes fabricating a second set of conductors in the back-side of the thinned substrate, the second set of conductors being below gates or active regions of at least the first set of transistors or the second set of transistors, being electrically coupled to at least the second set of transistors, and being embedded in the thinned substrate. In some embodiments, the method further includes fabricating a second set of vias on the back-side of the thinned substrate, the second set of vias being electrically coupled to at least the second set of transistors. In some embodiments, the method further includes depositing a second conductive material on the back-side of the thinned substrate on a second metal level thereby forming a third set of conductors, the third set of conductors being electrically coupled to at least the second set of transistors by the second set of vias, the second set of conductors comprising a second read word line, the second set of transistors being configured to receive a second read word line signal on the second read word line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a cross-latch including a first storage node and a second storage node;
a first transistor of a first type, the first transistor including a first gate extending in a first direction, and being on a first level;
a second transistor of a second type different from the first type, and the second transistor including a second gate on a second level below the first level;
a third transistor of the first type, and being coupled to the first storage node, the third transistor including a third gate on the first level;
a fourth transistor of the second type, and being coupled to the first storage node, the fourth transistor including a fourth gate on the second level; and
a first read bit line extending in a second direction different from the first direction, the first read bit line being on a first metal layer above a front-side of a substrate, and being coupled to the third transistor and the fourth transistor;
wherein the third transistor and the fourth transistor correspond to at least a first port of the device.

2. The device of claim 1, wherein
each of the second gate, the third gate, and the fourth gate extend in the first direction,
the first gate and the third gate are separated from each other in the second direction, and
the second gate and the fourth gate are separated from each other in the second direction.

3. The device of claim 2, further comprising:
a first gate isolation layer between the first gate and the second gate, the first gate isolation layer configured to electrically insulate the first gate and the second gate from each other.

4. The device of claim 2, further comprising:
a first pass-gate transistor of the first type, the first pass-gate transistor including a fifth gate on the first level; and
a second pass-gate transistor of the second type, and the second pass-gate transistor including a sixth gate on the second level,
wherein the fifth gate and the sixth gate extend in the first direction, the fifth gate and the third gate are separated from each other in the first direction, and the sixth gate and the first gate are separated from each other in the first direction.

5. The device of claim 4, wherein the cross-latch comprises:
a first inverter coupled to the first storage node, the second storage node, the first pass-gate transistor, the second pass-gate transistor, the third gate of the third transistor and the fourth gate of the fourth transistor; and
a second inverter coupled to the first storage node, the second storage node, the first pass-gate transistor and the second pass-gate transistor.

6. The device of claim 5, further comprising:
a first write bit line extending in the second direction, being on the first metal layer, and being coupled to the second pass-gate transistor;
a first write bit line bar extending in the second direction, being on the first metal layer, and being coupled to the first pass-gate transistor;
a first read word line extending in the second direction, being on the first metal layer, and being coupled to the first transistor;
wherein the first write bit line, the first write bit line bar, the first read word line, and the first read bit line are separated from each other in the first direction.

7. The device of claim 6, further comprising:
a first write word line extending in the second direction, being on a second metal layer below a back-side of the substrate, the second metal layer being different from the first metal layer, and being coupled to the first pass-gate transistor from the back-side of the substrate;
a second write word line extending in the second direction, being on the second metal layer, and being coupled to the second pass-gate transistor from the back-side of the substrate; and
a first read word line bar extending in the second direction, being on the second metal layer, and being coupled to the second transistor from the back-side of the substrate;
wherein the first write word line, the second write word line, and the first read word line bar are separated from each other in the first direction.

8. The device of claim 7, further comprising:
a seventh gate on the second level, and being electrically coupled to the fifth gate;
an eighth gate on the second level, and being electrically coupled to the sixth gate;
a first via electrically coupling the first read word line and the first gate together, the first via being between the first read word line and the first gate;
a second via electrically coupling the first write word line and the seventh gate together, the second via being between the first write word line and the seventh gate;
a third via electrically coupling the second write word line and the sixth gate together, the third via being between the second write word line and the sixth gate; and
a fourth via electrically coupling the first read word line bar and the second gate together, the fourth via being between the first read word line bar and the second gate.

9. The device of claim 7, further comprising:
a first contact extending in the second direction, being on a third level, and being electrically coupled to a source/drain of the first pass-gate transistor;
a second contact extending in the second direction, being on the third level, and being electrically coupled to a source/drain of the second pass-gate transistor; and
a third contact extending in the second direction, being on the third level and a fourth level different from the third level, and being electrically coupled to a source/drain of the third transistor, and a source/drain of the fourth transistor.

10. The device of claim 9, further comprising:
a first via electrically coupling the first write bit line bar and the first contact together, the first via being between the first write bit line bar and the first contact;
a second via electrically coupling the first write bit line and the second contact together, the second via being between the first write bit line and the second contact; and
a third via electrically coupling the first read bit line and the third contact together, the third via being between the first read bit line and the third contact.

11. A device, comprising:
a pair of inverters coupled to a first storage node and a second storage node;
a first transistor stack on a substrate, the first transistor stack comprising:
a first transistor of a first type, the first transistor including a first gate extending in a first direction, and being on a first level; and
a second transistor of a second type different from the first type, and the second transistor including a second gate extending in the first direction, and being on a second level below the first level;
a second transistor stack on the substrate, the second transistor stack comprising:
a third transistor of the first type, and being coupled to the first storage node, the third transistor including a third gate extending in the first direction, and being on the first level; and
a fourth transistor of the second type, and being coupled to the first storage node, the fourth transistor including a fourth gate extending in the first direction, and being on the second level;
a first conductor extending in a second direction different from the first direction, the first conductor being on a first metal layer above a front-side of the substrate, being coupled to the third transistor and the fourth transistor, and being configured as a first read bit line; and
a second conductor configured as a second read bit line extending in the second direction different from the first direction, the second conductor being on a second metal layer below a back-side of the substrate, and being coupled to the third transistor and the fourth transistor, and the second metal layer being different from the first metal layer.

12. The device of claim 11, further comprising:
a third transistor stack on the substrate, the third transistor stack comprising:
a first pass-gate transistor of the first type, the first pass-gate transistor including a fifth gate on the first level; and
a first dummy transistor including a sixth gate extending in the first direction, and being on the second level; and
a fourth transistor stack on the substrate, the fourth transistor stack comprising:
a second pass-gate transistor of the second type, and the second pass-gate transistor including a seventh gate extending in the first direction, and being on the second level; and
a second dummy transistor including an eighth gate extending in the first direction, and being on the second level;
wherein the fifth gate and the third gate are separated from each other in the first direction, the seventh gate and the first gate are separated from each other in the first direction, the sixth gate and the fourth gate are separated from each other in the first direction, and the eighth gate and the second gate are separated from each other in the first direction.

13. The device of claim 12, further comprising:
a third conductor extending in the second direction, being on the first metal layer, being coupled to the second pass-gate transistor, and being configured as a first write bit line;
a fourth conductor extending in the second direction, being on the first metal layer, being coupled to the first pass-gate transistor, and being configured as a first write bit line bar; and
a fifth conductor extending in the second direction, being on the first metal layer, being coupled to the first transistor, and being configured as a first read word line;
wherein the first conductor, the second conductor, the third conductor, the fourth conductor, and the fifth conductor are separated from each other in the first direction.

14. The device of claim 13, further comprising:
a sixth conductor extending in the second direction, being on the second metal layer, being coupled to the first pass-gate transistor from the back-side of the substrate, and being configured as a first write word line;
a seventh conductor extending in the second direction, being on the second metal layer, and being coupled to the second pass-gate transistor from the back-side of the substrate, and being configured as a second write word line; and
an eighth conductor extending in the second direction, being on the second metal layer, and being coupled to the second transistor from the back-side of the substrate, and being configured as a first read word line bar;
wherein the sixth conductor, the seventh conductor, and the eighth conductor are separated from each other in the first direction.

15. The device of claim 14, further comprising:
a first via electrically coupling the fifth conductor and the first gate together, the first via being between the fifth conductor and the first gate;
a second via electrically coupling the sixth conductor and the sixth gate together, the second via being between the sixth conductor and the sixth gate;
a third via electrically coupling the seventh conductor and the eighth gate together, the third via being between the seventh conductor and the eighth gate; and
a fourth via electrically coupling the eighth conductor and the second gate together, the fourth via being between the eighth conductor and the second gate;
wherein the sixth gate is electrically coupled to the fifth gate, and
the eighth gate is electrically coupled to the seventh gate.

16. The device of claim 14, further comprising:
a first contact extending in the second direction, being on a third level, and being electrically coupled to a source/drain of the first pass-gate transistor;
a second contact extending in the second direction, being on the third level, and being electrically coupled to a source/drain of the second pass-gate transistor; and
a third contact extending in the second direction, being on the third level and a fourth level different from the third level, and being electrically coupled to a source/drain of the third transistor and a source/drain of the fourth transistor.

17. The device of claim 16, further comprising:
a first via electrically coupling the fourth conductor and the first contact together, the first via being between the fourth conductor and the first contact;
a second via electrically coupling the third conductor and the second contact together, the second via being between the third conductor and the second contact;
a third via electrically coupling the first conductor and the third contact together, the third via being between the first conductor and the third contact; and
a fourth via electrically coupling the second conductor and the third contact together, the fourth via being between the second conductor and the third contact.

18. The device of claim 11, further comprising:
a first gate isolation layer between the first gate and the second gate, the first gate isolation layer configured to electrically insulate the first gate and the second gate from each other.

19. A method, comprising:
fabricating a first set of transistors and a second set of transistors in a front-side of a substrate, the first set of transistors being stacked above the second set of transistors;
fabricating a first set of vias on the front-side of the substrate, the first set of vias being electrically coupled to at least the first set of transistors;
depositing a first conductive material on the front-side of the substrate on a first metal level thereby forming a first set of conductors, the first set of conductors being electrically coupled to at least the first set of transistors by the first set of vias, the first set of conductors including a first read word line and a first read bit line, the first set of transistors being configured to receive a first read word line signal on the first read word line and a first read bit line signal on the first read bit line from the front-side;
performing thinning on a back-side of the substrate opposite from the front-side;
fabricating a second set of conductors in the back-side of the thinned substrate, the second set of conductors being below gates or active regions of at least the first set of transistors or the second set of transistors, being electrically coupled to at least the second set of transistors, and being embedded in the thinned substrate;
fabricating a second set of vias on the back-side of the thinned substrate, the second set of vias being electrically coupled to at least the second set of transistors;
depositing a second conductive material on the back-side of the thinned substrate on a second metal level thereby forming a third set of conductors, the third set of conductors being electrically coupled to at least the second set of transistors by the second set of vias, the second set of conductors comprising a second read word line, the second set of transistors being configured to receive a second read word line signal on the second read word line.

20. The method of claim 19, wherein the second set of conductors further comprises a second read bit line, and the second set of transistors being further configured to receive the first read bit line signal on the second read bit line from the back-side.
